(19) United States
(12) Patent Application Publication
(10) Pub. No.: US 2016/0084919 A1
(43) Pub. Date: Mar. 24, 2016

(54) METHODS AND APPARATUS FOR DETECTION OF TRANSIENT INSTABILITY AND OUT-OF-STEP CONDITIONS BY STATE DEVIATION

(71) Applicant: UNIVERSITY OF SASKATCHEWAN, Saskatoon, SK (CA)

(72) Inventors: Ramakrishna GOKARAJU, Saskatoon (CA); Binod SHRESTHA, Regina (CA); Parikshit A. SHARMA, Regina (CA)

(73) Assignee: UNIVERSITY OF SASKATCHEWAN, Saskatoon, SK (CA)

(21) Appl. No.: 14/889,572

(22) PCT Filed: May 6, 2014
(86) PCT No.: PCT/CA2014/050432

§ 371 Date: Nov. 6, 2015

Related U.S. Application Data
(60) Provisional application No. 61/820,072, filed on May 6, 2013.

(51) Int. Cl. G01R 31/40; G01R 25/00; G01L 1/00; G01R 21/00

(52) U.S. Cl. CPC G01R 31/40; G01R 21/00; G01R 25/00; G01L 1/00

(57) ABSTRACT

This application describes a state deviation technique for identifying transient instabilities in power systems. Such instabilities may result from disturbances such as external faults and power swing conditions. Detection of transient instabilities is based on the direction of change of phase angle of a machine such as a generator at an equilibrium point. Method and apparatus as disclosed may also be used for assessing system-wide transient stability of a power system or portion thereof.

### CROSS-REFERENCE TO RELATED APPLICATION

This application claims priority from U.S. Application No. 61/820,072 filed 6 May 2013. For purposes of the United States, this application claims the benefit under 35 U.S.C. §119 of U.S. Application No. 61/820,072 filed 6 May 2013 and entitled METHODS AND APPARATUS FOR DETECTION OF TRANSIENT INSTABILITY AND OUT-OF-STEP CONDITIONS BY STATE DEVIATION which is hereby incorporated herein by reference for all purposes.

### TECHNICAL FIELD

The invention relates to electrical power generation and power systems. Example embodiments provide methods for detecting transient instabilities and/or out-of-step conditions in synchronous generators. Other example embodiments provide power system protection systems that comprise systems for detecting transient instabilities and/or out-of-step conditions.

### BACKGROUND

An electrical power grid can be very complicated. Multiple generators may supply electrical power to multiple loads by way of many interconnected transmission lines. A wide range of control and protection equipment (e.g. fast governors, automatic voltage regulators, power system stabilizers, tap-changing transformers, flexible alternating current systems—FACTS, etc.) may normally regulate the voltage and frequency of the grid within tight limits.

Synchronous machines (e.g. synchronous generators or synchronous motors) connected to the grid are affected by electrical conditions on the grid and also affect electrical conditions on the grid. A synchronous generator produces an AC output having a frequency that depends on the speed of rotation of the generator. A typical synchronous generator has a rotor that is mounted on a shaft for rotation relative to a stator. The rotor is driven, by a prime mover—for example by an engine, steam turbine, water-driven turbine, wind turbine or other prime mover. In stable operation the mechanical torque delivered by the prime mover is balanced by electromagnetic forces acting on the rotor and the speed of rotation of the generator therefore remains constant.

The electromagnetic forces acting on the generator rotor depend in significant part on the flow of electrical power between the generator and the electrical grid to which the generator is connected. This flow of electrical power can be affected by events affecting the grid such as short circuits or other faults, large loads coming on-line or going offline, line switching, other generators coming online or going offline, protection circuits cutting off connections in the grid and the like. Such disturbances cause the voltage, current, and frequency to deviate from their nominal values.

During steady state (normal operating) conditions, in each of the generators connected to a power system a balance is maintained between the mechanical input and the electrical output of the generator. Similarly, there is a balance between the electrical power output of the generators and the electrical power consumed by loads of the power system.

Synchronous generators interconnected in a power system run at synchronous speeds with a constant relative rotor angle separation between them, with the frequency of the system remaining close to the nominal frequency (usually 60±1 Hz in North America and 50±1 Hz in some other countries). A typical voltage and current waveform during the steady state operation of a power system is shown in FIG. 1A.

Power systems are often subjected to various types of disturbances (faults, changes in power system configuration, loss of excitation, line tripping, loss of generation, large load changes, etc.). Such disturbances can cause sudden changes in the electrical power output of a generator connected to the power system.

When a disruption in the power system alters the power being drawn from a generator, the balance between torque provided by the prime mover and electromagnetic forces acting on the generator rotor can be disrupted. In the short period immediately after the disturbance, the mechanical input to the generator is typically relatively constant. The unbalance between the mechanical power driving the generator and the electromagnetic forces on the generator rotor can cause acceleration of the generator rotor (deceleration is included in acceleration. Deceleration is merely acceleration with a negative magnitude). Acceleration of the generator rotor alters the phase angle of the voltage and current waveforms of the electrical power produced by the generator relative to that of the grid to which the generator is connected. The acceleration of the generator rotor can affect the electrical power output by the generator which, in turn affects the electromagnetic forces on the generator rotor.

The result is that disruptions in a power system can cause oscillations in the rotors synchronous machines connected to the power system. This results in an electromagnetic oscillation in the system that causes fluctuation in the magnitude and phase of the voltages and currents throughout the system. As a result, the power flow between the various parts of the system also starts oscillating. Such a power system phenomena is known as a power swing. The waveforms for both voltage and current during a power swing condition are shown in FIG. 1B.

Power system engineers design the system to withstand variations in voltage, current, power, and frequency as long as they are within their desired operating limits (maximum steady state operating range of ±5% for voltage, ±1% for frequency, and so on). The standards for these operating limits are laid out in standards documents prepared by the IEEE (USA), IEC (Europe), CIGRE (France) etc. Standards applicable in North America are described in the IEEE Power System Reliability Committee (PSRC) report. If the separation of voltage angle between the tie line buses in an interconnected system goes beyond 180 degrees, the generators start to slip poles, leading to an asynchronous operation of the generators, eventually causing a sustained power oscillation in the system.

The evolution of the state of a power system following a disturbance depends upon various factors such as the magnitude of a disturbance, action of the control equipment, initial operating point, and the existence of damping and synchronizing torques in each machine.

Power swings can be classified into two categories: stable power swings and unstable power swings. A power swing that damps out and reaches a new steady state operating point is referred to as a “stable swing”. A power swing that goes through a sustained oscillation is referred to as an “unstable swing” or a “rotor angle instability condition”.

Deviations resulting from some disturbances may be self-curing in that the power grid may tend to return to its nominal stable-state conditions after such disturbances. Other small disturbances can be handled by control devices (e.g. automatic voltage regulators, power system stabilizers, flexible alternating current transmission systems controllers (FACTS) etc.) that bring the power grid back to a normal condition. However, typical currently-available control devices cannot handle certain deviations resulting from large disturbances. Such large disturbances can lead the system to an unstable condition. Protection systems are necessary to safeguard power systems from such unstable conditions.

The response of a power system to a disturbance can be considered in various time scales. A short time scale (‘first swing’) considers the initial response of the power system to a disturbance. A longer time scale (multi-swing) considers the longer-term response of the power system to the disturbance. Multi-swing responses may take into account the behaviours of various protective systems such as excitation control systems, grid control devices and the like. The response of a system to certain disturbances may appear stable when only a first swing is considered and may appear unstable on a longer multi-swing time scale. The time scales over which a power system responds can vary depending on the sizes of the generators involved. For example, smaller generators typically react to disturbances on shorter time scales than larger generators. For some power systems, first swing events typically occur within a few seconds (e.g. within about 1 second or within about 3 seconds or so of a disturbance). Multi-swing conditions typically occur over a period of a few seconds to more than 30 seconds.

An instability condition, if not prevented, may lead a power system into an unstable operation. The imbalance between the output electrical power and input mechanical power for generators caused by a large disturbance results in the acceleration of generators in one region with respect to the generators in another region. This leads to an angular separation of generators between two regions that may keep increasing until the kinetic energy gained is converted into potential energy. In a condition when the angular separation between two regions exceeds 180 degrees, pole-slipping starts and the system loses synchronism or falls “out-of-step”. To prevent damage to the system and/or to prevent instabilities from spreading it can be desirable to detect when a system is trending toward an out-of-step condition and to trip breakers and/or initiate the operation of other control or protective devices in response to such a determination (e.g. by generating suitable alarm signals).

The operation of protection systems can themselves affect operation of the grid. It can be undesirable to operate such protection systems unless they are needed. There is a need for methods and apparatus which can be applied to make early and accurate determinations of whether or not transient deviations in the state of a power grid are stable or unstable.

Another issue facing modern power systems is the trend toward generation of power from sources that can fluctuate significantly. A prime example is wind power systems. Maintaining stability of the overall power system in the presence of such fluctuating inputs can present significant technical problems.

Various technologies exist for evaluating stability of power systems. One examples is described in: Wiszniewski et al. US2013\0041604A1 entitled “Method of Predicting Transient Stability of a Synchronous Generator”. Other examples are described in: WO2010/003282A1; U.S. Pat. No. 8,369,055B2; U.S. Pat. No. 8,326,589B2; U.S. Pat. No. 8,248,061B2; U.S. Pat. No. 8,200,461B2; U.S. Pat. No. 7,761,402B2; U.S. Pat. No. 7,457,088B2; U.S. Pat. No. 6,833,711B1; U.S. Pat. No. 4,791,573A; US2011/0312498A1; US2011/0022240A1; and US2006/0152866A1. Other examples are described in:
K. H. So, J. Y. Heo, C. H. Kim, R. K. Aggarwal, and K. B. Song, “Out-of-step detection algorithm using frequency deviation of voltage,” IET Generation, Transmission & Distribution, vol. 1, no. 1, pp. 119-126, 2007.
K. R. Padiyar and S. Krishna, “Online detection of loss of synchronism using energy function criterion,” IEEE Transactions on Power Delivery, vol. 21, no. 1, pp. 46-55, 2006.
F. Gomez, U. D. Annakage, A. D. Rajapakse, and I. T. Fernando, “Support vector machine-based algorithm for post-fault transient stability status prediction using synchronized measurements,” IEEE Transactions on Power Systems, vol. 26, no. 3, 2011.
C. Cecati and H. Latafat, “Time domain approach compared with direct method of lyapunov for transient stability analysis of controlled power system,” in International Symposium on Power Electronics, Electrical Drives, Automation and Motion, Sorrento, Italy, June 2012, pp. 695-699.
S. Kalyani, M. Prakash, and G. A. Ezhilarasi, “Transient stability studies in smib system with detailed machine models,” in International Conference on Recent Advancements in Electrical, Electronics and Control Engineering, Sivakasi, India, December 2011, pp. 459-464.
W. Suampun and H. Chiang, “Critical evaluation of methods for estimating stability boundary for transient stability analysis in power systems,” in Power and Energy Society General Meeting, IEEE, Minneapolis, Minn., July 2010.
Y. Yare and G. Venayagamoorthy, “Real-time transient stability assessment of a power system during energy generation shortfall,” in Innovative Smart Grid Technologies (ISGT), Gaithersburg, Md., January 2010.
W. Kaipeng, Z. Yiwei, C. Lei, and M. Yong, “Computation of unstable equilibrium points on the transient stability boundary of power systems with detailed generator modeling” in Universities Power Engineering Conference (UPEC), 2009 Proceedings of the 44th International, Glasgow, United Kingdom, September 2009.
P. Mooney and N. Fischer, “Application guidelines for power swing detection on transmission systems,” in Power Systems Conference: Advanced Metering, Protection, Control, Communication, and Distributed Resources, Clemson, S.C., March 2006, pp. 159-168.
F. Plumptre, S. Brettschneider, A. Hiebert, M. Thompson, and M. Mynam, “Validation of out-of-step protection with a real time digital simulator,” in proceedings of the 60th Annual Georgia Tech Protective Relaying Conference, Atlanta, Ga., May, 2006.
C. Taylor, J. Haner, L. Hill, W. Mittelstadt, and R. Cresap, “A new out-of-step relay with rate of change of apparent resistance augmentation,” IEEE Transactions on Power Apparatus and Systems, vol. PAS-102, no. 3, pp. 631-639, March 1983.
   E. Farantatos, R. Huang, G. J. Cokkinides, and A. P. Meliopoulos, “A predictive out of step protection scheme based on pmu enabled dynamic state estimation,” IEEE PES General Meeting, Detroit, Mich., July 2011.
   Y. Xue, T. Van Custem, and M. Ribbens-Pavella, “Extended equal area criterion justifications, generalizations, applications,” IEEE Transactions on Power Systems, vol. 4, no. 1, pp. 44-52, 1989.
V. Centeno, A. Phadke, A. Edris, J. Benton, M. Gaudi, and G. Michel, “An adaptive out-of-step relay,” IEEE Transactions on Power Delivery, vol. 12, no. 1, pp. 61-71, 1997.
M. Bozchalui and M. Sanaye-Pasand, “Out of step relaying using phasor measurement unit and equal area criterion,” in Power India Conference, 2006 IEEE, New Delhi, India, April 2006, p. 6
W. Rebizant and K. Feser, “Fuzzy logic application to out-of-step protection of generators,” in Proc. IEEE Power Engineering Society Summer Meeting, Vancouver, Canada, vol. 2, July 2001, pp. 927-932.
   A. Abdelaziz, M. Irving, M. Mansour, A. El-Arabaty, and A. Nosseir, “Adaptive protection strategies for detecting power system out-of-step conditions using neural networks,” Generation, Transmission and Distribution, IEE Proceedings—, vol. 145, no. 4, pp. 387-394, July 1998.
A. D. Rajapakse, F. Gomez, K. Nanayakkara, P. A. Crossley, and V. V. Terzija, “Rotor angle instability prediction using post-disturbance voltage trajectories,” IEEE Transactions on Power Systems, vol. 25, no. 2, pp. 947-956, 2010.
Tziouvaras and D. Hou, “Out-of-step protection fundamentals and advancements,” in Proc. 57th Annual Conference for Protective Relay Engineers, College Station, Tex., March 2004, pp. 282-307.

These and other technologies for out-of-step detection and transient stability determination have various disadvantages. Some technologies require setting various thresholds that must be customized for particular power systems. Determining what settings should be used to provide reliable operation in a particular power system can be complex. For example determining appropriate settings of the blinders in blinder-based techniques can require large numbers of stability studies. Setting such thresholds can be especially difficult in larger power systems with many generators. Since such settings are based on a system configuration and loading conditions which change as the years go by it is necessary to periodically review the settings to ensure proper operation.

Some technologies apply artificial intelligence or pattern recognition to detect out-of-step or unstable conditions. Examples of such technologies include neural networks, funzzy logic, and support vector machine methods which require offline training for a given system configuration.

Some technologies evaluate stability based in part on time derivatives of values (especially second time derivatives) that may be affected by numerical calculation errors and/or electrical noise thereby resulting in unreliable determinations.

There remains a need for alternative practical and robust methods and apparatus that can be applied to evaluating transient stability of power systems and/or detect out-of-step conditions in power systems.

### SUMMARY

This invention has a range of different aspects. One aspect provides methods for evaluating transient stability of power systems. Another aspect provides systems for detecting instabilities in power systems. Another aspect provides numerical relays that include systems for evaluating transient stability of a power system.

One aspect of the invention provides methods for assessing transient stability of a power system (and/or detecting out-of-step conditions). The methods comprise obtaining a measure, Pm, of mechanical power driving a synchronous machine and obtaining a measure, Pe, of electrical power output by the machine. If the difference, (Pm−Pe), of Pm and Pe changes sign from negative to positive, the method determines a sign of a measure, ω, of a rate that a phase angle of the synchronous machine is changing relative to a reference phase angle and generates an output signal based on the sign of ω. It is not mandatory that the sign of ω be determined only if the sign of Pm−Pe changes from negative to positive. At the cost of some computation one could determine the sign of ω each time an operating point of the system passes through a point where Pm=Pe and use the sign of ω in those cases where the sign of Pm−Pe changes from negative to positive. The output signal may be applied to trigger a protective device, place a protective device into an ‘armed’ or ‘ready’ mode, provide an informational warning, provide an alarm or the like.

In some embodiments obtaining Pe comprises monitoring voltage and current at an output of the synchronous machine. In some embodiments monitoring the voltage and current is performed locally to a processor in which the method is being performed. Some embodiments involve encoding measures of the voltage and current, transmitting the encoded measures to a processor at a location remote from the output of the synchronous machine and processing the encoded measures to provide the output signal at the remote location.

In some embodiments the synchronous machine comprises a computed equivalent to a plurality of physical machines. For example, the synchronous machine may comprise a single machine infinite bus (SMIB) equivalent machine. The method may comprise computing parameters of the equivalent machine.

Another aspect provides apparatus for monitoring power systems that is configured to perform a method according to the invention. The apparatus may comprise a standalone apparatus or may be integrated into other apparatus such as a protective device such as a relay or breaker, a regulating device such as a control system for a generator, a power system, or an area within a power system or the like.

Another aspect provides power systems and power system protection systems and power system components which incorporate apparatus and/or perform methods as described herein.

Further aspects of the invention as well as features of example embodiments are described herein and/or illustrated in the accompanying drawings.

### BRIEF DESCRIPTION OF THE DRAWINGS

Exemplary embodiments are illustrated in referenced figures of the drawings. It is intended that the embodiments and figures disclosed herein are to be considered illustrative rather than restrictive.

FIG. 1A shows current and voltage waveforms for a generator in normal, stable operation.

FIG. 1B shows current and voltage waveforms for a generator experiencing a power swing condition.

FIG. 2 is a block diagram showing a system according to an example embodiment.

FIG. 3 is a flow chart illustrating a method according to an example embodiment.

FIG. 4A is a plot showing an example function mapping power angle to electrical power.

FIG. 4B is a plot showing an example function mapping time to a rate of change of a rotor angle, ω, for an example stable power swing.

FIG. 4C is a plot showing an example function mapping time to relative speed ω for an example unstable power swing.

FIG. 5 is a schematic diagram of a 12-bus test system that is currently being standardized by the IEEE.

FIG. 6A is a plot of output electrical power and relative speed ω against time in generator G4 of FIG. 5 during an example sustained three phase fault applied for the duration of 22 cycles.

FIG. 6B is a plot of power deviation against speed deviation for generator G4 during the example sustained three phase fault of FIG. 6A.

FIG. 6C is a plot of bus voltage angle against time for generator G4 during the example sustained three phase fault of FIG. 6A.

FIG. 7A is a plot of electrical output power and speed against time in generator G4 of FIG. 5 during an example sustained three phase fault applied for a duration of 26.4 cycles.

FIG. 7B is a plot of power deviation against speed deviation for generator G4 during the example sustained three phase fault of FIG. 7A.

FIG. 7C is a plot of a bus voltage angle against time for generator G4 during the example sustained three phase fault of FIG. 7A.

FIG. 8A is a plot of electrical output power and speed against time for generator G2 of FIG. 5 during an example sustained three phase fault applied for a duration of 22 cycles.

FIG. 8B is a plot of power deviation against speed deviation for generator G2 during the example sustained three phase fault of FIG. 8A.

FIG. 8C is a plot of bus voltage angle against time for generator G2 during the example sustained three phase fault of FIG. 8A.

FIG. 9A is a plot of electrical output power and speed against time in generator G2 of FIG. 5 during an example sustained double line to ground fault applied for a duration of 14 cycles.

FIG. 9B is a plot of power deviation against speed deviation for generator G2 during the example sustained double line to ground fault of FIG. 9A.

FIG. 9C is a plot of a bus voltage angle against time for generator G2 during the example sustained double line to ground fault of FIG. 9A.

FIG. 10A is a plot of electrical output power and speed against time in generator G2 of FIG. 5 during an example multiswing instability caused by an example sustained three phase fault applied for a duration of 18 cycles.

FIG. 10B is a plot of power deviation against speed deviation for generator G2 during the example multiswing instability of FIG. 10A.

FIG. 10C is a plot of a bus voltage angle against time for generator G2 during the example multiswing instability of FIG. 10A.

FIG. 11A is a plot of a SMIB equivalent electrical power and speed against time for an example sustained three-phase fault applied for a duration of 16 cycles at a point on a bus of the IEEE 12-bus grid of FIG. 5.

FIG. 11B is a plot of power deviation against speed deviation for an example stable power swing resulting from the fault of FIG. 11A.

FIG. 11C is a plot of a SMIB equivalent electrical power and speed against time for an example sustained three-phase fault applied for a duration of 20 cycles at a point on a bus of the IEEE 12-bus grid of FIG. 5.

FIG. 11D is a plot of power deviation against speed deviation for an example unstable power swing resulting from the fault of FIG. 11A.

FIG. 12 is a diagram showing how voltage across a breaker can vary depending on voltage angle and illustrating that switching a breaker at a time when voltage angle is relatively small can reduce the voltage across the breaker at the time the switching is performed.

FIG. 13 is a schematic diagram of a 39-bus test system.

FIG. 14 is a plot of SMIB equivalent electrical power and relative speed or a fault applied at bus BUS15 of the test system of FIG. 13 and cleared after 120 ms.

FIG. 15 is a plot of power deviation vs. speed deviation for a fault applied at bus BUS15 of the test system of FIG. 13 and cleared after 120 ms

FIG. 16 is a plot of voltage angle difference between series elements for a fault applied at bus BUS15 of the test system of FIG. 13 and cleared after 120 ms.

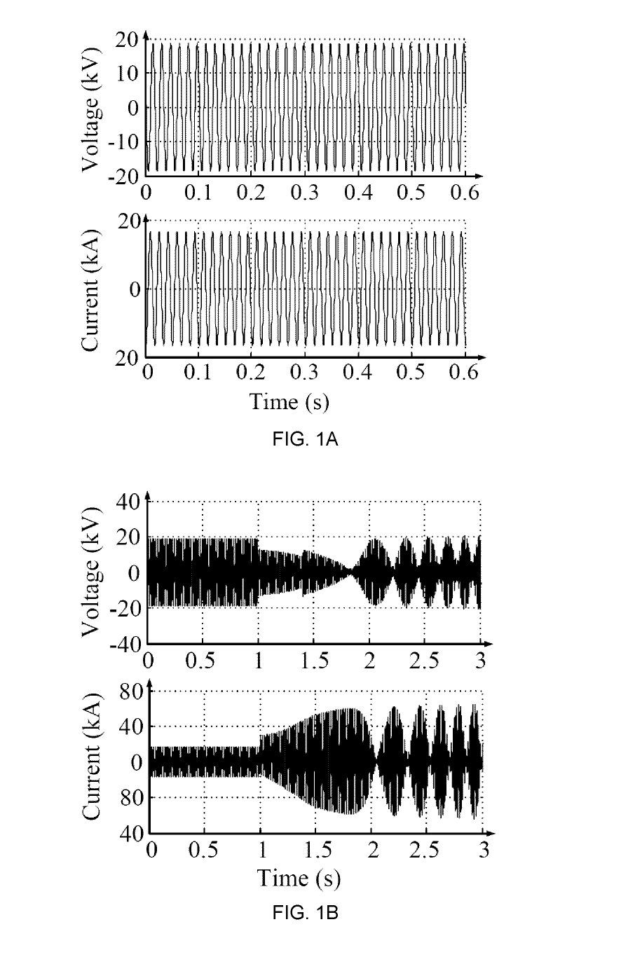

### DESCRIPTION

Throughout the following description specific details are set forth in order to provide a more thorough understanding to persons skilled in the art. However, well known elements may not have been shown or described in detail to avoid unnecessarily obscuring the disclosure. Accordingly, the description and drawings are to be regarded in an illustrative, rather than a restrictive, sense.

Apparatus according to some embodiments of the invention monitors a combination of parameters of an electrical power system that includes a synchronous generator. Based on the monitored parameters the apparatus evaluates stability of the power system and/or watches for the onset of an out-of-step condition. The monitored parameters include, and in some cases consist essentially of 1) electrical power parameters and 2) relative speed parameters. The apparatus is configured to analyze deviations in these parameters (which may be called ‘state variables’) to determine transient stability of the monitored power system.

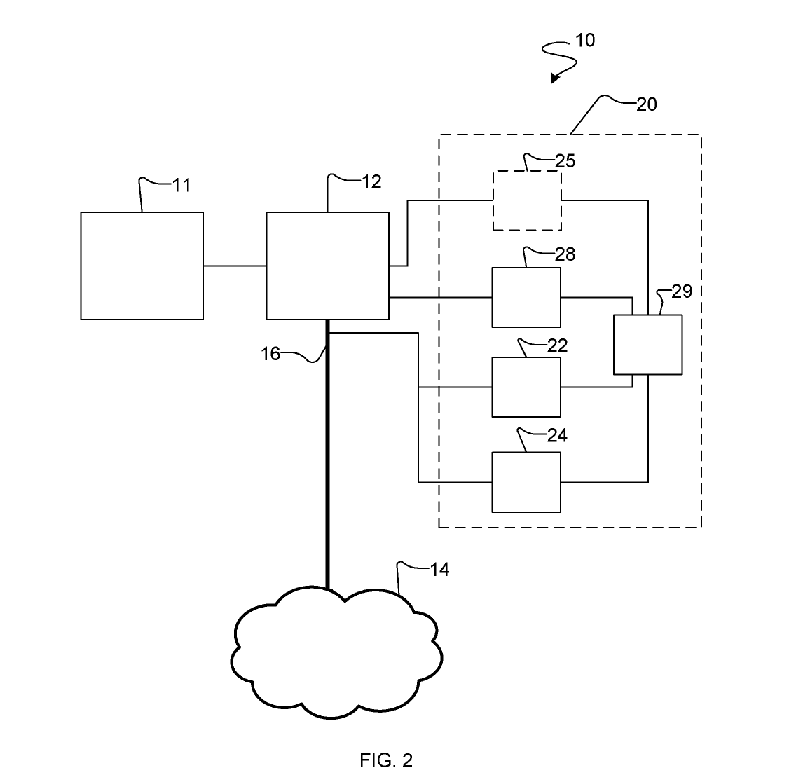

FIG. 2 shows schematically apparatus 10 according to an example embodiment. Apparatus 10 includes a prime mover 11 connected to drive a synchronous generator 12 which is connected to supply electrical power to a power grid 14 by way of a transmission line 16. Power grid 14 may comprise any combination of electrical systems. Power grid 14 typically comprises one or more additional generators, various loads, various transmission lines, various switches, various power grid control components etc. Power grid 14 may comprise, for example, the North American power grid, the European power grid, the Japanese power grid, a regional power grid or some subset of any of these.

A stability monitor 20 comprises a current monitor 22 and a voltage monitor 24. Current monitor 22 and voltage monitor 24 may, for example be connected at terminals of generator 12 or at a suitable location along transmission line 16. Current monitor 22 and voltage monitor 24 may have any suitable construction. Current and voltage monitors for power systems are commercially available. In some embodiments current monitor 22 and voltage monitor 24 each comprise signal processing electronics that may include filters and voltage transformers that pre-process current and voltage waveforms for digitization by one or more analog-to-digital converters (ADCs). The digitized current and voltage signals may be further pre-processed in the digital domain (for example by digital filtering) to yield current and voltage signals for further processing.

A phasor estimation algorithm may be applied to obtain the magnitude and the phase of the measured current and voltage. There are many different phasor estimation algorithms that may be applied for this purpose. For example, stability monitor 20 may use the Fourier Transform, or some variation or alternative thereof such as the least squares method, Kalman filtering, or some other spectral estimation method, and possibly some form of averaging to determine the magnitude and phase of the current and voltage being monitored. In some embodiments, stability monitor 20 may also use other algorithms such as waveform-model algorithms to determine at least one of the peak value of sinusoidal current, the fundamental frequency of voltage and current phasors, the magnitude of harmonics of current waveforms, or the like.

An optional tachometer 25 is connected to measure a speed of rotation of the rotor of generator 12. Tachometer 25 is optional because the speed of rotation of generator 25 can be determined from the frequencies of signals detected by voltage monitor 24 and/or current monitor 22.

Generator 12 is most typically a multi-phase generator (e.g. a three-phase generator). In such embodiments, current monitor 22 and/or voltage monitor 24 may separately monitor each phase. Wires for the three separate phases are not indicated in FIG. 2. In FIG. 2 transmission line 16 may be a multi-phase transmission line such as a three-phase transmission line.

A mechanical power monitor 28 monitors the mechanical power driving generator 12. Mechanical power monitor 28 may, for example, comprise a torque meter connected to measure a torque in a drive shaft or other member transmitting mechanical power to drive generator 12, (mechanical power may be determined from this torque and the rotational speed of generator 12) and/or an indirect power measurement such as an operating parameter of prime mover 11. A mechanical power meter 28 that directly measures mechanical values such as shaft RPM, forces torques or the like is not required in all embodiments. As mentioned in the background section above, under steady-state conditions, mechanical power driving a generator can be determined from the electrical power output by the generator. Consequently in some embodiments mechanical power monitor 28 may comprise a circuit or processor configured to process signals representing the electrical power output of generator 12 immediately prior to a disturbance (e.g. in a previous time step) to yield an estimate of the mechanical power being supplied to drive generator 12.

Stability monitor 20 comprises a processing system 29 configured to evaluate stability of power system 10 based on the measurements made by current monitor 22, voltage monitor 24 and mechanical power monitor 28.

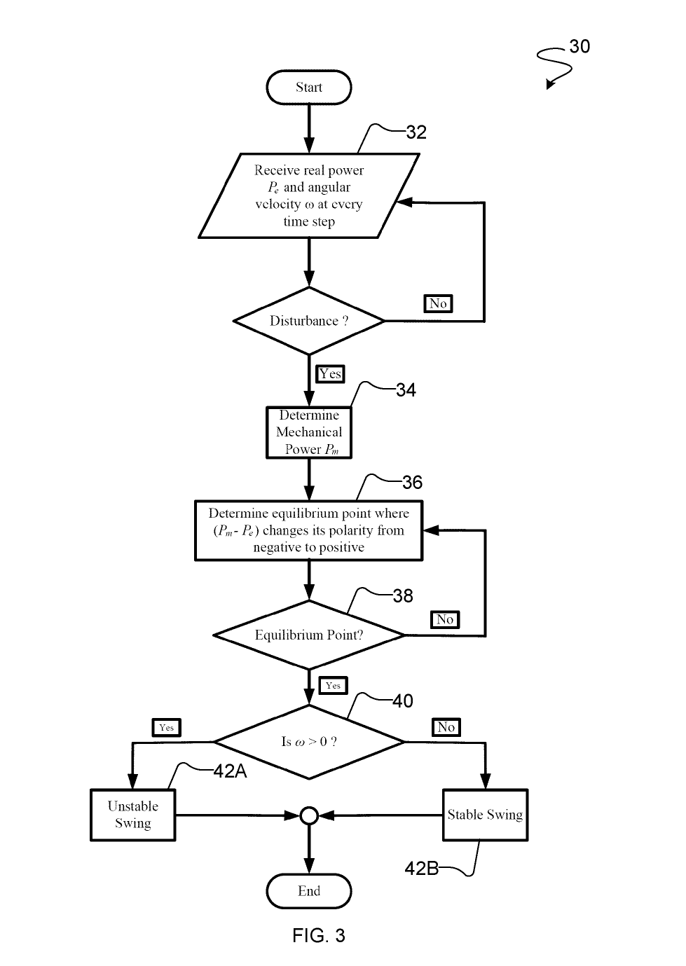

FIG. 3 is a flow chart illustrating a method 30 according to an example embodiment. Method 30 is illustrated as comprising a series of distinct steps. Method 30 could be implemented in the alternative by a plurality of continuous operations.

In an example embodiment the steps of method 30 are performed in each of a series of time steps. In block 32 the real power Pe being delivered by generator 12 and the angular velocity of generator 12 are determined.

Real power may be determined from the voltage and current monitored respectively by a current monitor 22 and a voltage monitor 24, for example. In some embodiments the monitored voltage and current are converted to symmetrical sequence components (e.g. positive sequence phasors). The power Pe may be determined, for example, in the absence of zero sequence components by calculating:

Pe=\sqrt{3}IV cos φ (1)

where: I is the magnitude of the positive sequence current phasors, V is the magnitude of the positive sequence voltage phasors and φ is the angle between the voltage phasors and the current phasors.

Angular velocity of generator 12 may be determined, for example, by computing a discrete Fourier transform (DFT) on the voltage signal to find the frequency of the voltage waveform. Another example way to determine angular velocity of generator 12 is to compute a rate of change (e.g. a time derivative or finite difference) of a voltage angle. A DFT involves more calculation but may be less susceptible to yielding inaccurate results in the presence of noise that may affect individual measurements of voltage angle.

Block 34 determines the mechanical power Pm driving generator 12. The mechanical power may be determined, for example, by any one or more of: direct measurement (e.g. measurement of torque and rotational speed of a drive shaft or other member driving generator 12) indirect measurement (e.g. measurement of a penstock flow for a hydro turbine powering a generator, a fuel consumption for an engine driving a generator, parameters for the steam supply to a steam-powered generator etc. which have a known relationship to the mechanical power supplied to a generator) or a mechanical power measure computed based on one or more prior measurements of electrical power output (one can assume that the mechanical power driving a generator after a fault will be essentially the same as the mechanical power driving the generator immediately prior to the fault).

Block 36 determines the current mechanical power Pm. As the electrical power Pe delivered by generator 12 changes and passes operating points where Pe=Pm, the sign of the difference between mechanical power input and electrical power output (Pm−Pe) changes.

Block 38 determines whether the real power Pe is at an equilibrium point. An equilibrium point is an operating point on a trajectory where Pe=Pm and the direction in which the operating point is travelling along the trajectory is such that the sign of (Pm−Pe) is changing from negative to positive as the state of the system passes through the point at which Pe=Pm. If not, method 30 returns to block 36.

If block 38 determines that the real power Pe is at an equilibrium point (within a suitable threshold) then method 30 proceeds to block 40 which determines whether ω, which is the rate of change of the rotor angle δ, is positive or negative. ω may be determined, for example, by subtracting the pre-disturbance synchronous frequency from the frequency of the power being produced by the generator.

The pre-disturbance synchronous frequency may be determined, for example, by monitoring and maintaining a record of the frequency of the generator output during steady-state pre-fault conditions. After a fault occurs the frequency recorded immediately pre-fault (or a function of one or more frequencies recorded immediately pre-fault) may be used as the synchronous frequency. This allows for drifts in the synchronous frequency from its nominal value. In alternative embodiments that may be applicable in some cases a nominal frequency is used as a pre-disturbance synchronous frequency.

Speed or frequency deviation may optionally be determined using local measurements of voltage phase angle. One way to do this is described in A. G. Phadke, J. S. Thorp, M. G. Adamiak, “A New Measurement Technique for Tracking Voltage Phasors, Local System Frequency, and Rate of Change of Frequency”, IEEE Transactions on Power Apparatus and Systems, vol. PAS-102, no. 5, May 1983, pp. 1025-1038.

In an example embodiment, speed/frequency is determined as follows. The speed is first calculated using two successive phase angle values of voltage V(k) and V(k−1) as follows:

$${ω}_{υ} ( k ) = \frac{arg ( V ( k ) ) - arg ( V ( k - 1 ) )}{T} \qquad ( 2 )$$

where, T is the sampling period. The average of co is then obtained over a data window of 2N+1 samples as given in equation (3):

$${ω}_{υ} = {\sum }_{k = - N}^{N} \frac{arg ( V ( k ) ) - arg ( V ( k - 1 ) )}{T} \qquad ( 3 )$$

In an example prototype embodiment N is 12 and the sampling period T is 1.3889 ms.

If ω is positive, method 30 proceeds to block 42A corresponding to an ‘unstable’ swing. If ω is negative, method 30 proceeds to block 42B corresponding to a ‘stable’ swing. Block 42A and/or 42B may perform further actions. For example, block 42A may trigger a protective device such as a relay.

In some embodiments, method 30 is triggered by a disturbance in the power system. For example, method 30 may be triggered when electrical power deviation exceeds a threshold. Electrical power deviation may be found by determining:

ΔPₑ=Pₑ|ₜ−Pₑ|ₜ_{₀} (4)

where: Pₑ|ₜ_{₀} is the steady-state electrical power measured prior to the disturbance and Pₑ|ₜ is the electrical power measured after the disturbance. Method 30 may be activated whenever the disturbance magnitude ΔPₑ is greater a predetermined threshold value such as 6% or 10%. This avoids unnecessary calculations. In an out-of-step relay implementation, method 30 may be triggered by a relay starter element, in such embodiments, method 30 may maintain pre-disturbance values for Pm and synchronous frequency (e.g. by monitoring voltage and current at one or more locations in a power system) but may defer other calculations until triggered by the relay starter element (so that method 30 operates only for disturbance conditions). In other embodiments, method 30 may operate continuously but the output of method 30 may be blocked or inhibited unless the block or inhibition is removed by operation of a relay starter element.

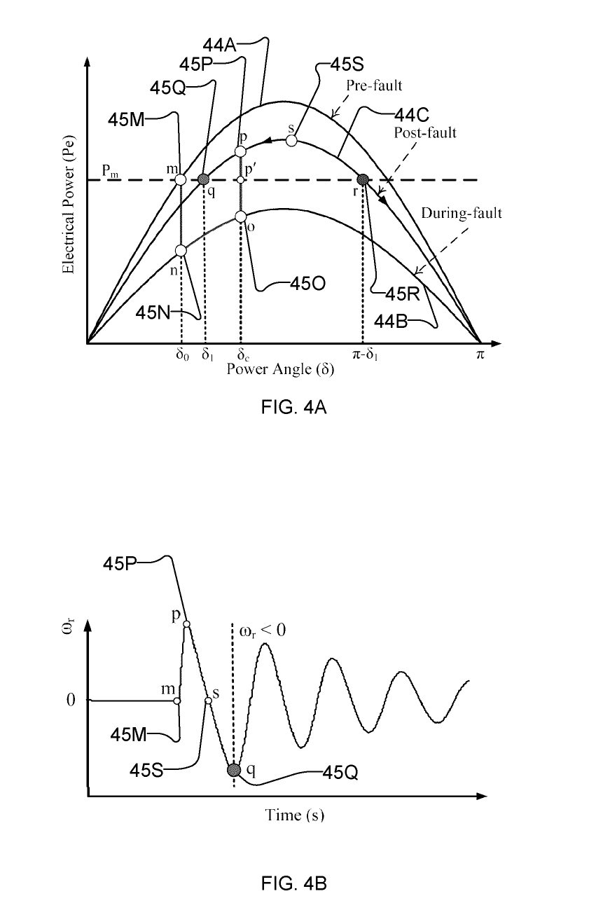

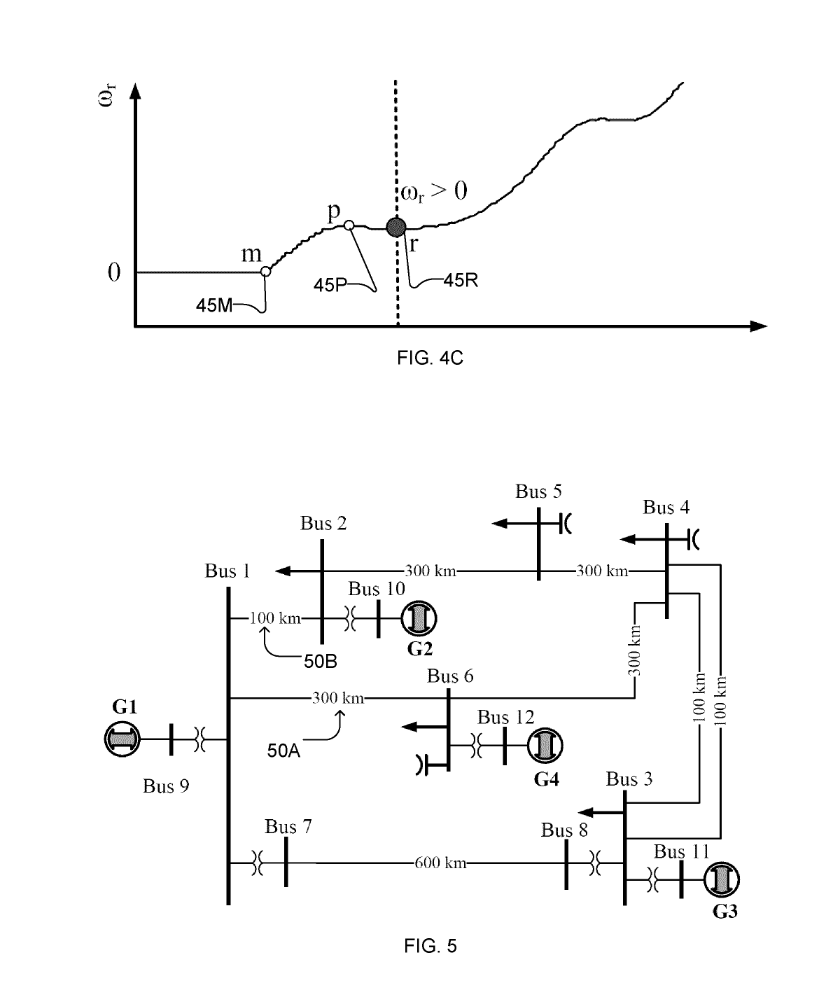

FIGS. 4A and 4B illustrate the operation of method 30. FIG. 4A is a plot showing electrical power output as a function of power angle. Curve 44A is for operation of a generator pre-fault. Curve 44B is for operation of the generator during a fault. Curve 44C is for operation of the generator at an instant of time after the fault. FIG. 4B shows ω as a function of time for an example stable power swing. FIG. 4C shows ω as a function of time for an example unstable power swing.

In block 38 of method 30 transient stability assessment is performed based on the generator speed at the equilibrium point. In typical cases, generator speed increases during a fault condition and starts to decrease after the fault is removed. Pre-fault, the generator operates in a steady state condition as shown by point 45M of FIG. 4A. After a fault occurs, the operating point moves to point 45N. The generator accelerates in the region containing operating points 45M-45N-45O-45P′ (because Pm−Pe is positive in this region). As a result of the acceleration, the operating point moves to point 45O at which point the fault is removed. After the fault is removed the operating point moves to point 45P. At point 45P the generator speed exceeds the synchronous speed. Consequently the rotor angle separation δ is increasing. At operating point 45P the generator rotor undergoes negative acceleration (because Pm−Pe is negative).

As shown in FIG. 4B, when the system is operating at point 45P the speed of the generator is greater than the synchronous speed (i.e. ω>0). Therefore the rotor angle δ continues to increase as the generator starts to decelerate. The stability of the generator depends on whether or not the generator regains synchronous speed (ω=0) before reaching operating point 45R. For example, if the synchronous speed is regained at point 45S (as in FIG. 4B), then after the system passes through operating point 45S the rotor angle δ will start to decrease and the operating point will move toward point 45Q. At point 45Q the generator rotor starts to undergo positive acceleration (because Pm−Pe is positive to the left of point 45Q in FIG. 4A). The generator will settle into a new steady state operating point 45Q after a few oscillations.

If the disturbance is large enough, the generator may oscillate to point 45R before it regains synchronous speed. To the right of operating point 45R (as shown in FIG. 4A) the mechanical output power exceeds the electrical power output of the generator (Pm−Pe is positive) and so the generator rotor will experience positive acceleration (so that ω will increase). To the left of operating point 45R (again as viewed in FIG. 4A) the mechanical output power is less than the electrical power output of the generator and so the generator rotor will experience negative acceleration (so that ω will decrease).

If the operating point of the generator moves to point 45R from the direction of point 45S then point 45R is an equilibrium point (since Pm=Pe at point 45R and the sign of Pm−Pe is changing from negative to positive) then the stability of the generator depends on the value of ω at point 45R. The generator will be unstable if ω is positive at point 45R (because the operating point will then continue to move to the right of point 45R into a region in which ω will continue to increase as shown in FIG. 4C).

It can be seen that at least some embodiments analyses the trajectory of operating points in a power versus speed deviation state plane. Power deviation can be readily measured on a transmission line or at terminals of a generator or other device by recording the power just before a disturbance and monitoring the power deviation (e.g. a difference between the power just before the disturbance and the power at an instant after the disturbance or a function thereof) in a continuous fashion. Power deviation may also or in the alternative be determined from measurements of generator mechanical power inputs and/or electrical power outputs.

Similarly, speed/frequency deviation may be measured from voltage signals representing local measurements of voltage as discussed in Phadke et al. (cited above) and/or calculated from generator rotor speeds.

In various embodiments, measurements of system parameters (e.g. voltages, power, speed/frequency) may be made locally to the apparatus being applied to predict transient stability and/or out-of-step conditions. For example, power deviations could be monitored at a location in the power system where it is desired to test for transient stability or where an out-of-step relay is located. In other embodiments, measurements may be made at one or more remote locations and transmitted to the apparatus using wide area measurements. Any suitable information transmission media and protocols may be used to carry information from remote measurements all or part of the way to an apparatus which applies those measurements as inputs to a method for detecting transient instability and/or out-of-step conditions as described herein.

Method 30 as described above may be practiced using as inputs only measurements of electrical power and the generator speed. Other inputs are not required. Both of these parameters may be obtained from online voltage and current measurements. The parameters used by the algorithm are easily available. An advantage of using generator speed as an input is that generator speed tends to change smoothly on the time scales of interest because of the inertia of the generator. Therefore, performance of the method may be less affected by switching transients than some other methods. Additional benefits of some embodiments are that the embodiments can be implemented without system network reduction. Additional benefits of some embodiments are that the embodiments can perform well in conjunction with generator controls such as excitation controls and governor controls.

Methods and apparatus as described above may be applied in the control of a power system such as a power grid. For example, a numerical relay may incorporate methods and apparatus as described above. The relay may comprise a switch and may be configured to open the switch upon the detection of a transient instability. In some embodiments, methods and/or apparatus as described herein are applied to provide out-of-step tripping (OST). OST trips selected breakers for an out-of-step condition. The tripping is initiated to disconnect a generator or a large power system area in order to ensure that stability is achieved for the rest of the generators or the individual islands separated from the unstable portion of the network.

A power system monitoring system may incorporate apparatus configured to perform methods as described above for evaluating transient stability and/or out-of-step conditions at one or more points in a power system. For example, the control system may be configured to monitor electrical current and voltage at outputs of one or more generators in the power system and to perform transient stability analysis using those outputs as described above. In response to a determination that one or more such generators is entering an unstable mode (e.g. is liable to go out-of-step) the control system may initiate protective action such as one or more of: triggering a protective relay; controlling the affected generator to mitigate the problem, generating alarm signals, and the like.

In some embodiments a power system includes a plurality of electrical generators and a control system is configured to apply the methods described herein to assess the transient stability of the power system at the system level using wide-area measurements. Wide area measurement system (WAMS) technology may be utilized. In an example system-wide assessment that applies the methods described herein, wide-area measurements include electrical power and speed signals measured at the terminals of each generator in the system. In some embodiments electrical power and speed measurements are also made at other synchronous machines (e.g. motors) in the system. In some embodiments, electrical power and frequency measurements are made at transmission stations and other points within a power system.

Technology as described herein may be applied to control the operation of protective devices to avoid undesired triggering of the protective devices. During a power swing, the voltage angle between two interconnected systems might reach 180 degrees, the voltages may fall to a minimum and the currents may rise to a maximum. Such an electrical condition can appear to be a fault to a protective relay. Relays designed to operate during faults in a power system may also operate during power swings. Relays such as an overcurrent, directional overcurrent, undervoltage, and distance relays may all be undesirably triggered to operate during a power swing. Current differential relays as are sometimes used to protect generators, transformers, buses and lines do not typically respond to power swings because a power swing condition appears as an external fault condition to such relays.

Undesired operation of protective devices due to stable or unstable power swings may severely impact the stability, security and reliability of a power system. Further, relays tripping at random locations because of the power swings can weaken a power system and create imbalance between demand and supply and may lead to cascading conditions—outages, loss of generations and loads.

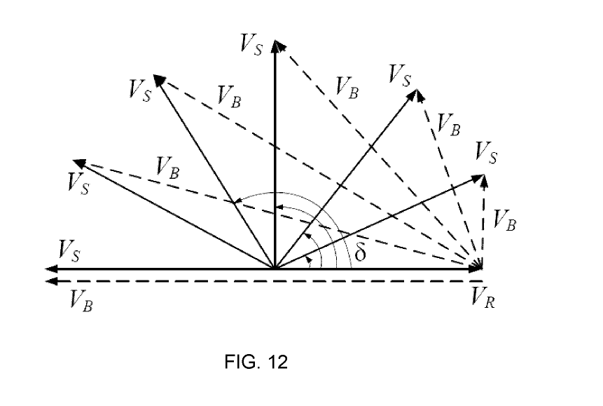

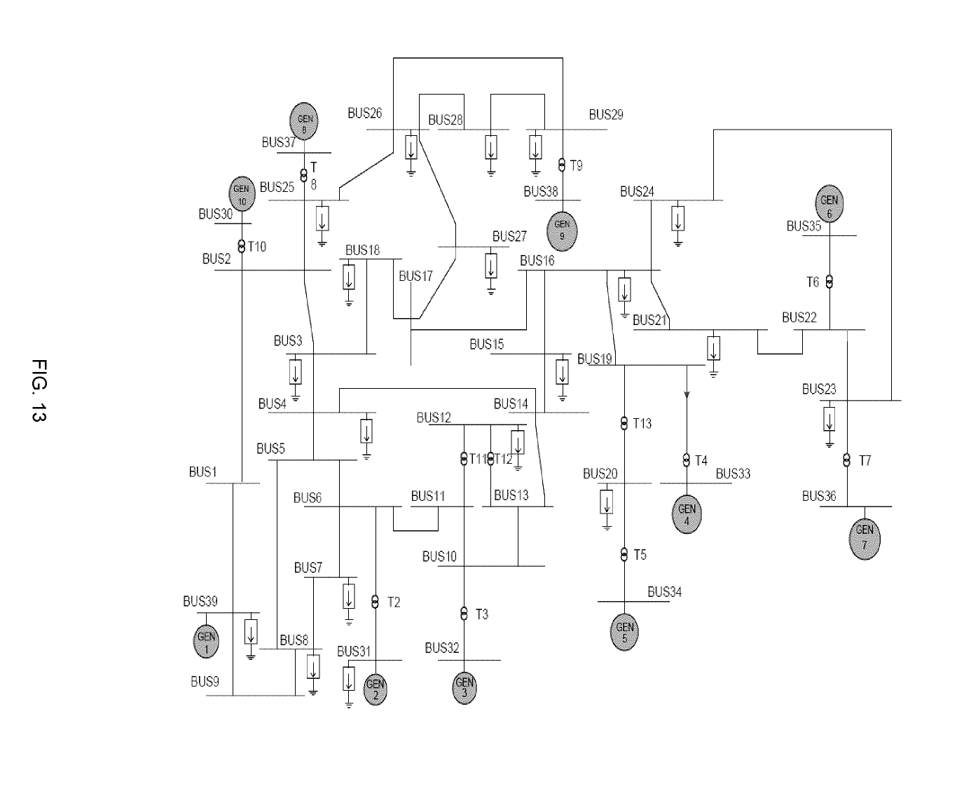

During an unstable response to a disturbance, the voltage angle difference for a generator can increase from its pre-fault value and reach 180 degrees past which the generator will slip poles. Example voltage values experienced by the breaker for different angles δ can be seen in FIG. 12. If the breaker operates at a lower voltage angle of separation for an imminent out-of-step condition, the life of the breaker can be extended. However, with most of the current out-of-step relaying technologies, the breakers operate at angle values closer to 180 degrees (when the voltage across the breaker can be as much as twice the normal value).

In some embodiments methods as described herein are applied to instability prediction and are capable of detecting instability early while the voltage angle of separation for the breaker is still fairly small, thereby reducing the potential for degradation of the breaker element. It is generally desirable for an out-of-step relay to be fast enough that tripping can be initiated before 120 degrees of voltage angle separation in order to minimize the voltage stress on the breaker. Fast detection also gives enough time to coordinate the operation of a range of other protective elements in the system. In some embodiments, reliable detection of instability or out-of-step conditions can occur when the voltage angle at a breaker is about 90 degrees or less.

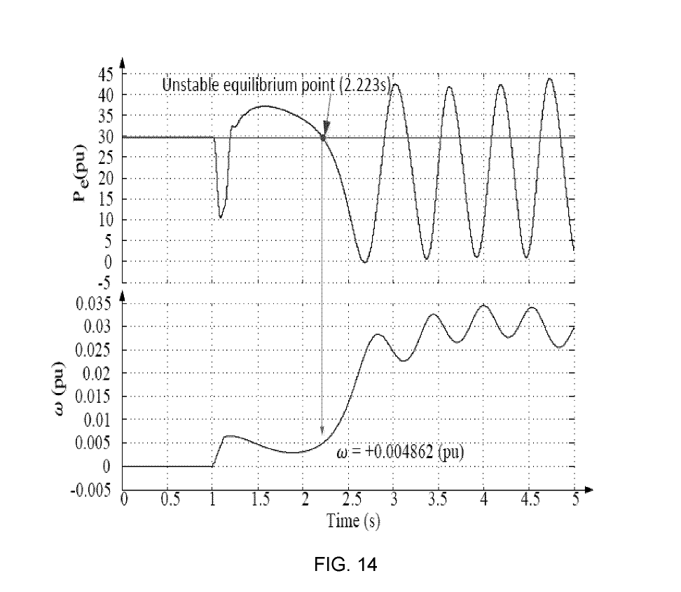

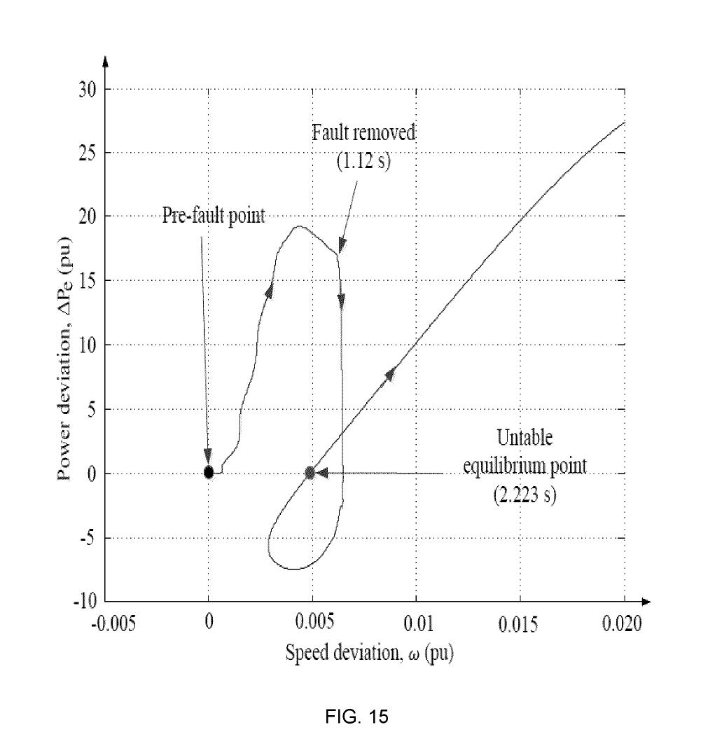

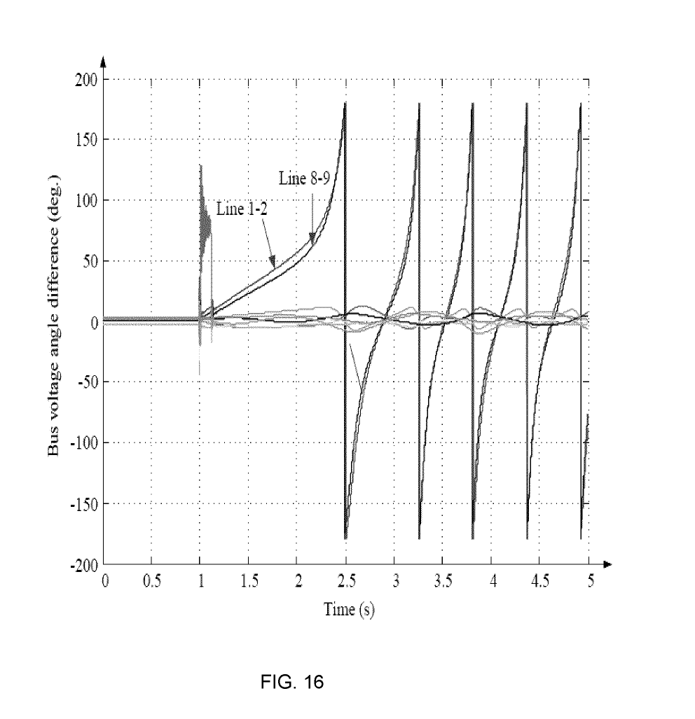

In an example simulation, a three phase fault was applied at bus BUS15 of the IEEE 39-bus test system shown in FIG. 13. A fault duration of 120 ms led to an unstable power swing. Following the disturbance, generators GEN2 to GEN10 separated from generator GEN1. The coherent generators GEN2 to GEN10 were represented by an equivalent machine forming one area and generator GEN1 was represented as a separate area. The SMIB equivalent parameters were calculated by the relay after determining the coherency of the generators. The plot of SMIB equivalent electrical power and relative speed, shown in FIG. 14, shows that the system becomes unstable. The instability is detected 1.223 s after the fault inception. The relative speed observed at the equilibrium point for the unstable case is ω=0.004862 p.u. FIG. 15 is a plot of power deviation versus speed deviation. FIG. 16 shows the angle between series elements for a fault at bus BUS15 for a duration of 120 ms. The simulation shows that the angle separation between buses BUS1 and BUS2 on one hand and buses BUS8 and BUS9 on the other hand goes beyond the acceptable limit and becomes unbounded.

In this simulation it was shown that instability is detected at a favourable (relatively small) angle of separation between the generators. For line 1-2 in FIG. 16, instability was detected at an angle difference of 76.8 degrees. For line 8-9 of FIG. 16, instability was detected at an angle difference of 68.8 degrees.

Because the method as described herein may be applied in a way that is not computationally intensive, time required for computation does not introduce significant latency. For example hardware calculation time on an ADSP-BF533 DSP board may be on the order of 1-2 ms or less (calculation times of <1.667 ms have been observed in real time testing).

It is most typically desirable to avoid triggering a protective device unless the protective device is required since, for at least some sorts of protective device, triggering the protective device can cause disturbances in a power system and/or temporarily impair the performance of the power system. On the other hand, for some applications it can be desirable to obtain an early warning of transient instability or an out-of-step condition even if the early warning is subject to an element of uncertainty.

In addition to applications in the control of relays and other protective equipment, methods and apparatus as described herein may additionally be applied to provide signals informing of a state of a power system. The signals may, for example, include warning signals that warn of impending transient instabilities and/or impending out-of-step conditions affecting a generator, area within a power system or an entire power system. Such signals may, for example, be applied to prepare protective equipment for operation. For example, such a signal may be applied to prepare a breaker for operation.

Alarm signals may be delivered to an operations centre. In some embodiments, protective relays, circuit breakers, and/or other power system equipment are configured to apply methods and apparatus as described herein to generate messages and alarms in the control centre in the case of disturbances. Operators at the control centre may select the relevant information, draw conclusions from the real-time data from the alarms in order to restore the power system to a secure state. Such action can help to avoid the spread of fault conditions to different parts of the power system. Trajectory plots using the state deviation approach as described herein may be used to activate alarm conditions in the control centre so that the system operators can prepare to take remedial action to prevent or reduce system instability and/or to prevent or reduce the spread of system instabilities to different and larger parts of the power system. The operators may, for example operate systems to perform system islanding and automatic load shedding in response to receiving such signals.

In some embodiments, at a control centre, there is a display that identifies different areas of a power system and provides a visual indication regarding alarms generated by the methods described herein. In some embodiments the display includes a display of a trajectory of an operating point in a power deviation/speed deviation state plane. In some embodiments, equilibrium points are displayed on the trajectory. The equilibrium points may be coloured, sized, or otherwise configured to indicate visually whether or not the methods described herein are predicting instability and/or an out-of-step condition.

In some embodiments, the state variables Pe and ω are monitored by a system that is configured to predict a future trajectory of an operating point defined by Pe and ω and to trigger an alarm based on the predicted trajectory. The trajectory may be predicted, for example by determining rates of change of Pe and ω. An alarm may be triggered, for example upon determining that the predicted trajectory will pass through an equilibrium point (i.e. a point where Pe=Pm and Pm−Pe changes from negative to positive when, at the equilibrium point, ω is predicted to have a value that is above a threshold (e.g. positive or zero). For example, method 30 may be applied to the predicted trajectory and the alarm may be triggered automatically upon method 30 detecting a transient instability or out-of-step condition based on analysis of the predicted trajectory.

Method 30 has been applied in a model of the 12-bus test system shown in FIG. 5 to detect transient instabilities. This test system is called the ‘IEEE 12-bus test system’ herein. The IEEE 12-bus test system was modelled using PSCAD/EMTDC software available from Manitoba HVDC Research Centre of Winnipeg, Canada.

In one simulation, a three phase fault was applied at point 50A in the middle of the transmission line connecting buses 1 and 6 to create both stable and unstable swings in generator G4. In this test scenario, generator G4 was loaded to 95% of its maximum capacity and generators G2 and G3 were loaded to 75% and 70% of their installed capacities, respectively. Several stable and unstable cases were created.

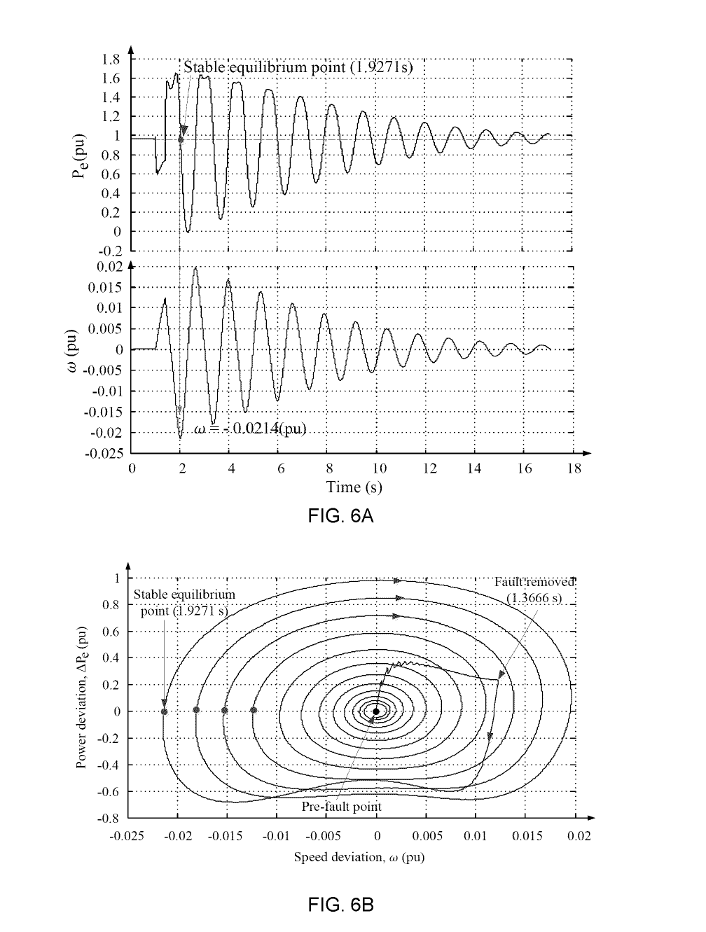

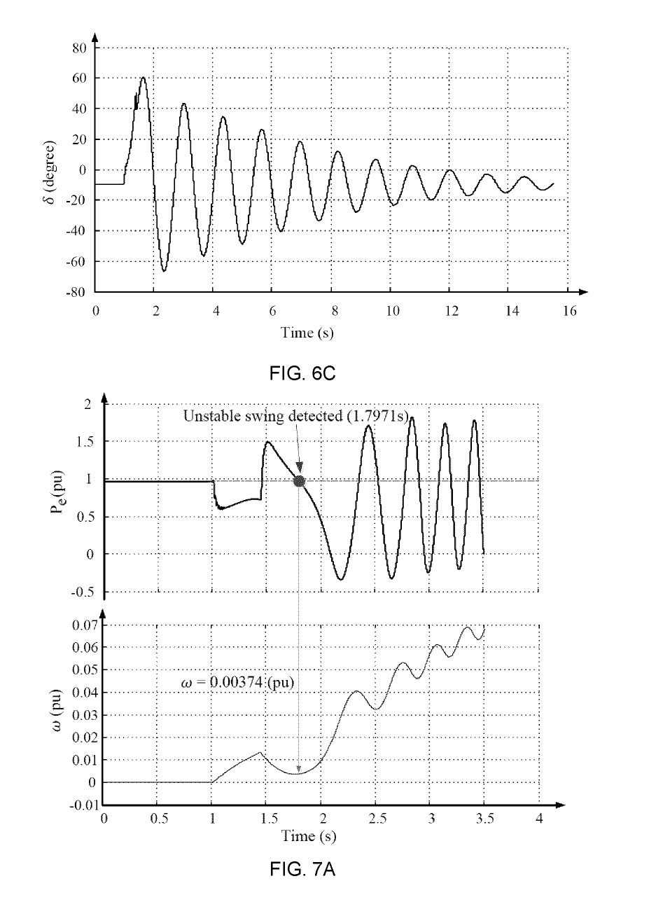

FIG. 6A is a plot of output electrical power and relative speed ω in generator G4 for a sustained three phase fault applied for the duration of 22 cycles (0.3665 s). FIG. 6B is a plot of power deviation versus speed deviation for generator G4. The relative speed at the first equilibrium point is ω=−0.0214 pu (368.94 rad/s), which detects the swing as stable. The corresponding plot of bus voltage angle for generator G4 is shown in FIG. 6C.

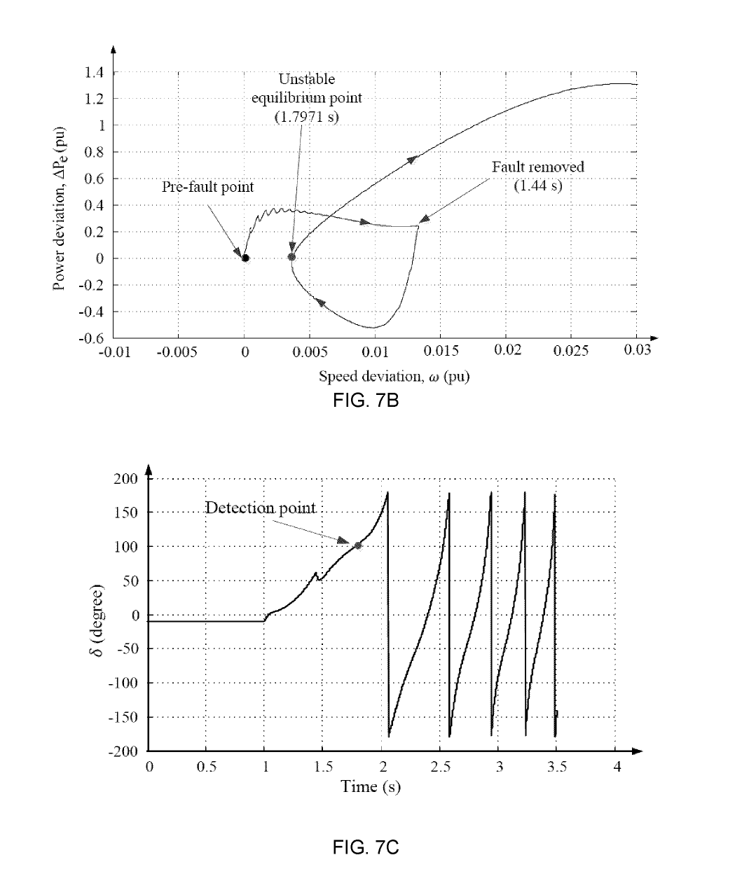

The same simulation was repeated with a fault duration of 26.4 cycles (0.44 s) applied at the same location. This disturbance led to an unstable swing in generator G4. FIG. 7A shows the plot of electrical output power and speed for a sustained three phase fault applied for a duration of 26.4 cycles (0.44 s). FIG. 7B is a plot of power deviation versus speed deviation for generator G4 during the simulation. At the equilibrium point, the speed of generator G4 is ω 0.00374 pu (378.41 rad/s), which is positive and hence an unstable swing is indicated. The instability was detected 0.7971 s after the fault inception and the terminal voltage angle of generator G4 at the time of detection was 101.9′. The plot of corresponding bus voltage angle for an unstable swing for generator G4 is shown in FIG. 7C. A summary of the simulation results for different fault durations is provided in Table I.

TABLE I
Summary of Simulation Results for Power Swings in Generator G4

| Fault Duration, | | | |
|---|---|---|---|
| cycles | Fault Duration, s | Detection Time, s | Decision |
| 14 | 0.2332 | 0.7300 | stable |
| 16 | 0.2666 | 0.7700 | stable |
| 18 | 0.2999 | 0.8100 | stable |
| 20 | 0.3332 | 0.8620 | stable |
| 22 | 0.3665 | 0.9271 | stable |
| 24 | 0.3998 | 1.0300 | stable |
| 26.4 | 0.4400 | 0.7971 | unstable |
| 28 | 0.4665 | 0.6732 | unstable |

In another simulation, a three phase fault was applied at point 50B in the middle of the transmission line connecting bus 1 and bus 2 to create both stable and unstable swings in generator G2. In this test scenario, generator G2 was loaded to 74% and generators G3 and G4 were loaded to 70% of their installed capacities. A sustained three phase fault for a duration of 22 cycles (0.3665 s) applied at point 50B led to an unstable swing in generator G2.

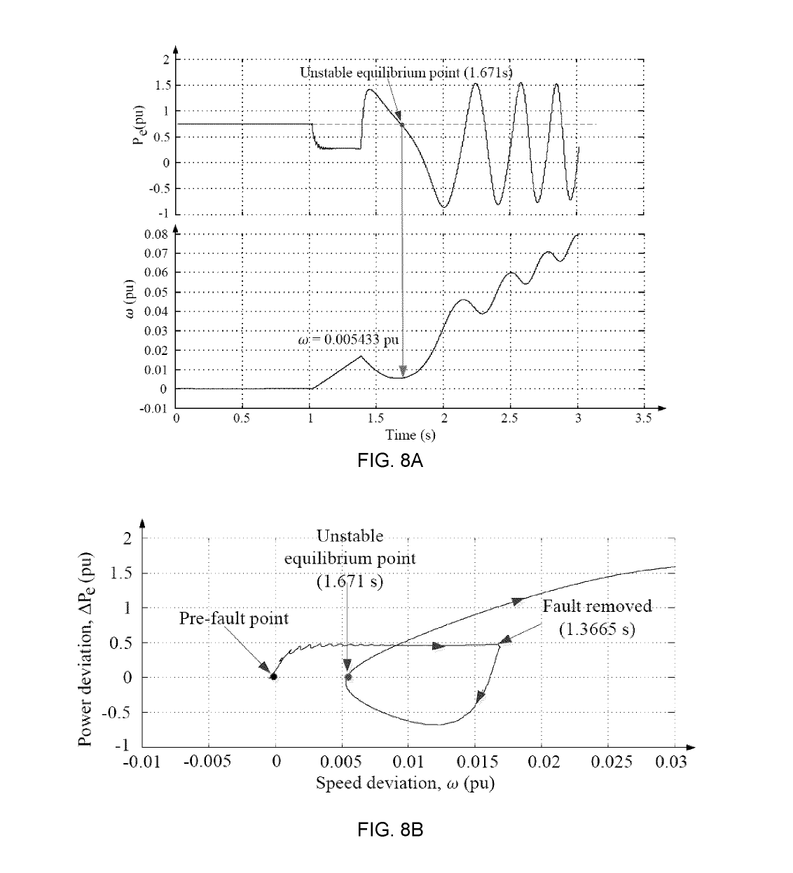

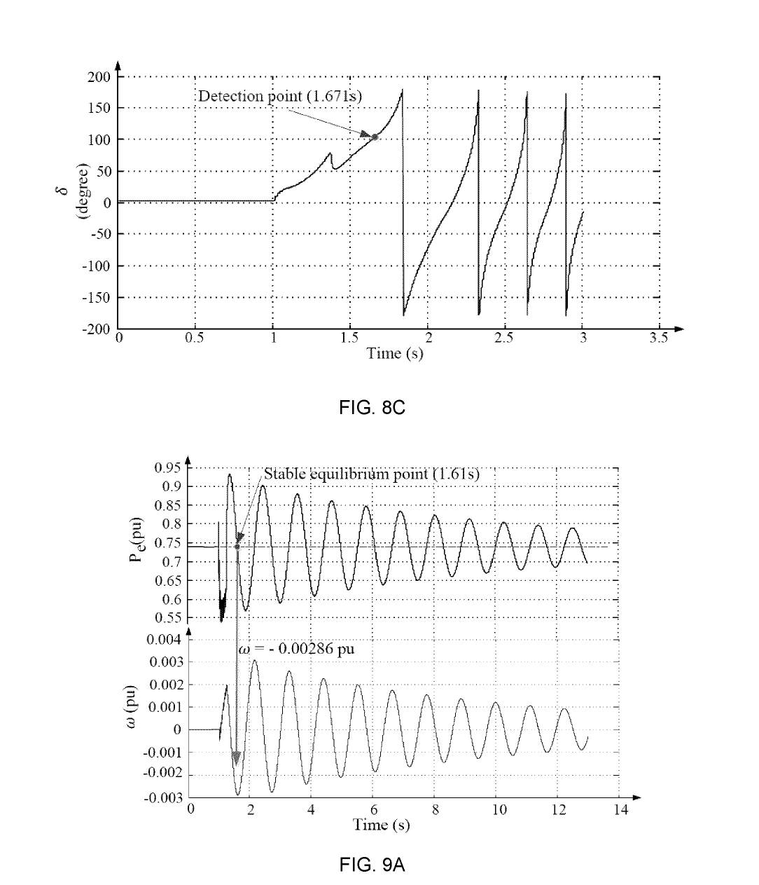

FIG. 8A is a plot of electrical output power and speed for generator G2 in a period including a sustained three phase fault applied for a duration of 22 cycles (0.3665 s) at point 50B. FIG. 8B shows the plot of power deviation versus speed deviation for generator G2. The speed of generator G2 is greater than the base speed (ω=0.005433 pu) at the equilibrium point and hence the swing is identified as being unstable. The detection time was found to be 0.671 s after the fault inception and the detection was made at a generator bus voltage angle of 106.7°. The plot of corresponding bus voltage angle for an unstable swing for generator G2 is shown in FIG. 8C. A summary of the simulation results for different fault durations is provided in Table II.

TABLE II
Summary of Simulation Results for Power Swings in Generator G2

| Fault Duration, | | | |
|---|---|---|---|
| cycles | Fault Duration, s | Detection Time, s | Decision |
| 12 | 0.2000 | 0.6755 | stable |
| 14 | 0.2333 | 0.7102 | stable |
| 16 | 0.2666 | 0.7500 | stable |
| 22 | 0.3665 | 0.6710 | unstable |
| 24 | 0.3998 | 0.5518 | unstable |

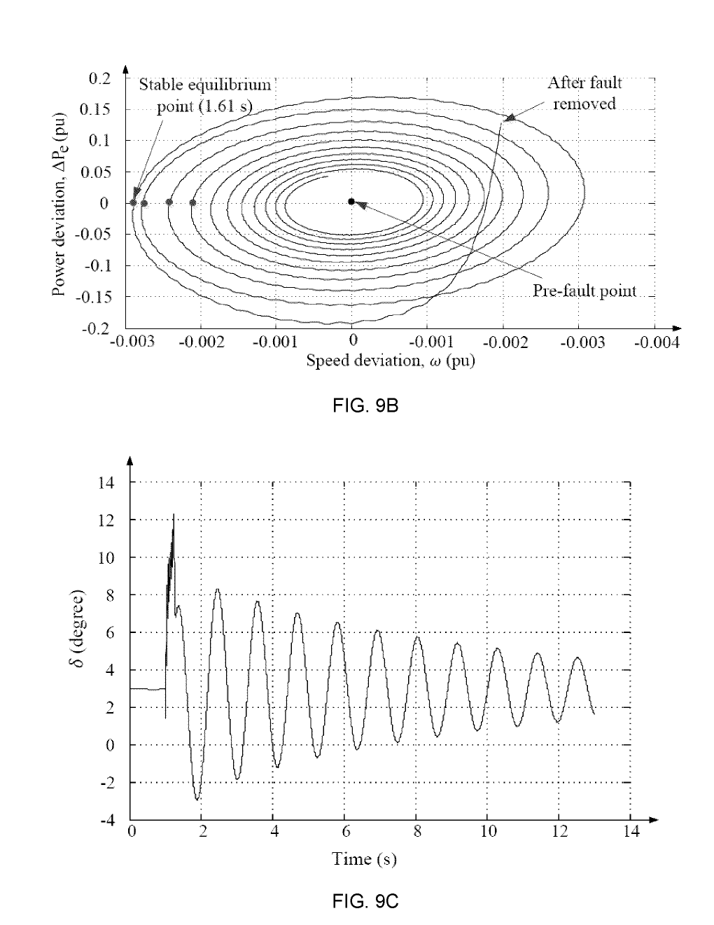

In another simulation a sustained double line to ground fault was applied for a duration of 14 cycles (0.2333 s). FIG. 9A is a plot of output electrical power and relative speed (ω) for generator G2 in this simulation. FIG. 9B is a plot of power deviation versus speed deviation for generator G2. The relative speed determined at the first equilibrium point is ω=−0.00286 pu, which indicates that the swing is stable. FIG. 9C is a corresponding plot of bus voltage angle for generator G2 as a function of time.

Another simulation demonstrated the ability of methods as described herein to detect multi-swing instabilities. In this simulation, generators G2, G3, and G4 were operated at 85% of their maximum capacity and a sustained three phase fault was applied at location 50C on bus 4 for a duration of 18 cycles (0.3 s). This deviation was found to cause a multi-swing instability for generator G2.

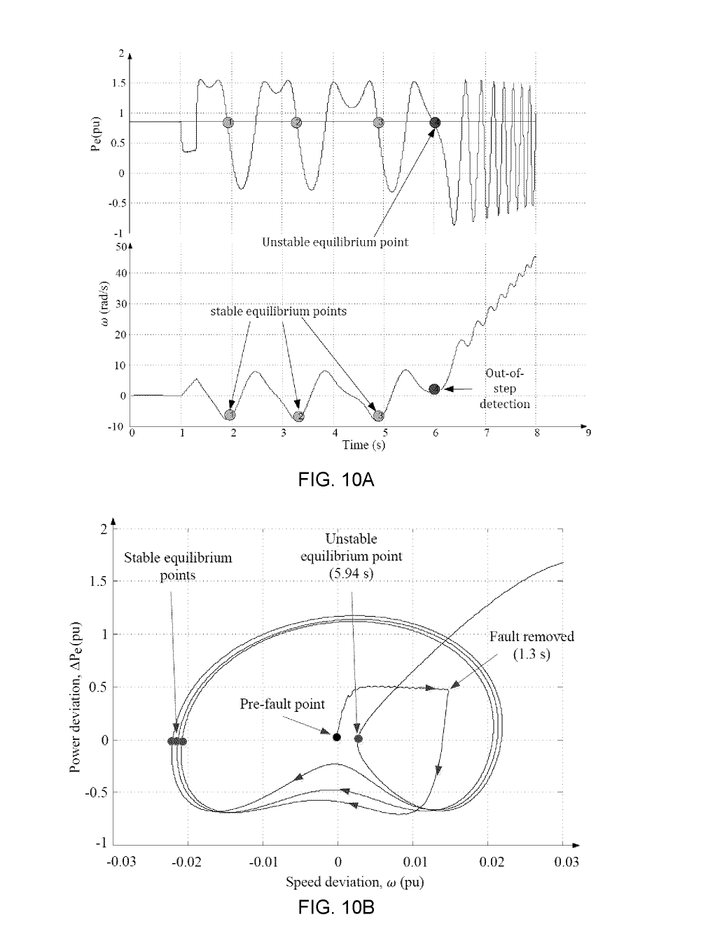

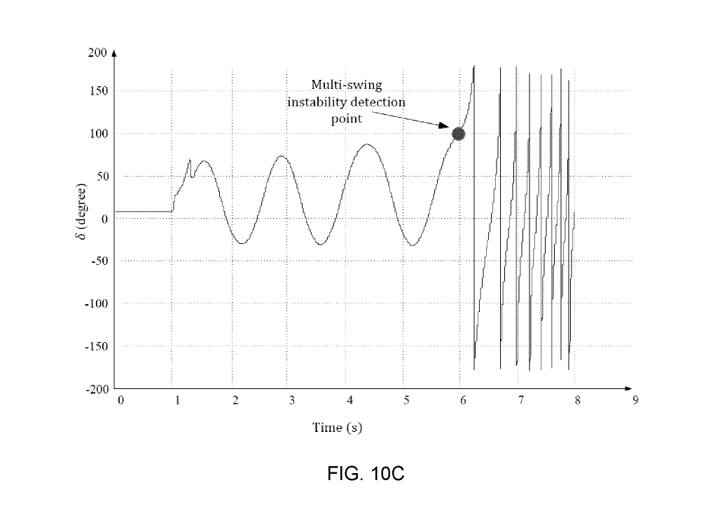

FIG. 10A is a plot of output electrical power and relative speed (ω) for the multi-swing unstable case for generator G2. The relative speed determined at the first equilibrium point is ω=−0.0207 pu, which indicates that the swing is stable. From FIG. 10A it can be seen that the first, second, and third power swings are all stable as determined by method 30. However, the fourth swing is determined to be unstable. The instability is detected 4.94 s after the fault inception. FIG. 10B is a plot of power deviation versus speed deviation for generator G2 for a period including the fault. FIG. 10C is a plot of generator bus voltage angle δ for generator G2 as a function of time for the multi-swing unstable case.

As noted above, methods as described in may be used locally in a power system or may be applied in system-wide stability assessment. In some embodiments methods as described herein are performed by measuring voltage and current at more or less the same place at which the methods are preformed. In other embodiments voltage and current are measured at one location and the measurements are processed by algorithms executed at one or more locations remote from the place where the measurements were made. Some embodiments make assessments based on measurements made for one specific machine (e.g. a particular generator) or at one location (e.g. a particular transmission line or at a particular substation).

Other embodiments acquire measurements of power system parameters at a number of locations spread around the power system. These other embodiments may process the distributed measurements using a simplified model of the power system (e.g. a SMIB model) to obtain a reduced number of parameters that are equivalent to the measured parameters and then perform analysis using the processed measurements. The distributed measurements (for example, Pm and Pe or other measurements from which Pm and Pe may be derived) may be made, for example, at all of the generator plants in a power system. The results of the measurements may be sent over a communication channel to the location where a relay or other control system implementing methods as described herein is located. In some embodiments the measurements are pre-processed before transmission to reduce the amount of data required to be transmitted. SMIB equivalent parameters may be determined on-line using these measurements.

When the present methods are applied to locally-acquired measurements there are generally no communication delays. In methods in which data is required to be transmitted to another location for analysis, inaccuracies could result from unequal latencies in the data transmission channel(s). This could be compensated for by introducing small delays to make the latencies more equal. Another issue that can arise when applying the methods described herein to distributed measurements is that mechanical power computed from line voltage and current at a location remote from generators may not equal the sum of mechanical power for multiple individual generators (because of variable losses in the system). Consequently, practicing methods as described herein using line voltages and currents measured remotely from individual generators may be less accurate than practicing the same methods using measurements made directly at all individual generators in a power system. This is typically not a major issue for protective relaying. In some embodiments, a small time delay may be introduced to ensure that a predicted instability is, in fact, materializing before triggering a protective device.

In one embodiment, system-wide stability assessment utilizes the WAMS (Wide Area Monitoring System) technology to gather real time signals from geographically distributed locations. The real time signals are used for calculating single-machine infinite-bus (SMIB) equivalent parameters. The electrical power output and speed measured at a generator location are used to calculate SMIB equivalent parameters in real time.

For example, the various devices and associated methods described herein can be used to predict the first swing out-of-step condition in a Single Machine Infinite Bus (SMIB) system as well as in larger power system configurations (e.g. two-area and IEEE 39-bus test systems) using system-wide information. This involves representing a plurality of generators with an SMIB equivalent system. The methods described herein may then be applied to the parameters of the SMIB equivalent system. For multi-machine systems, analysis can be performed, such as coherency analysis for example, to identify critical groups of generators. The critical generator groups are then represented with an SMIB equivalent system, and the state plane method may be applied to the SMIB equivalent system.

Following a disturbance, the system is decomposed into two groups: one consisting of the critical machine(s) and the other consisting of the rest of the system. Such decomposition is understood to those of skill in the art and is described in Y. Xue, T. Van Custem, and M. Ribbens-Pavella, “Extended equal area criterion justifications, generalizations, applications,” IEEE Transactions on Power Systems, vol. 4, no. 1, pp. 44-52, 1989, for example.

The calculation of SMIB equivalent parameters starts following the disturbance and identification of two areas. The quantities measured in real time from the generator location and the inertia constants of the generators may be applied to find SMIB equivalent parameters, such as Pe and ω using the following equations:

$$\begin{matrix}{P}_{e} = ( {M}_{a} {\sum }_{i ∈ B} {P}_{ei} - {M}_{b} {\sum }_{j ∈ A} {P}_{ej} ) {M}_{T}^{- 1} & ( 5 ) \\ ω = {ω}_{s} - {ω}_{a} \\ where \text{:} & ( 6 ) \\ {ω}_{s} = \frac{1}{{M}_{b}} {\sum }_{i ∈ B} {M}_{i} {ω}_{i} \\ and & ( 7 ) \\ {ω}_{a} = \frac{1}{{M}_{a}} {\sum }_{j ∈ A} {M}_{j} {ω}_{j} & ( 8 )\end{matrix}$$

In these Equations, Ma is the inertia constant of the equivalent generator for a first area (area A) Mb is the inertia constant of the equivalent generator for a second area (area B), Mi is the inertia constant for the ith individual generator in area B, Mj is the inertia constant for the jth individual generator in area A, MT is the sum of the inertia constants of all of the generators in areas A and B, Pei is the electric power being produced by generator i and Pej is the electrical power being produced by generator j. Method 30 or a variation thereof may then be applied to the SMIB equivalent parameters.

In some embodiments, a system is configured to automatically divide generators of a power system into different groups after a disturbance. In at least one embodiment, coherency analysis is applied to separate a plurality of generators in a power system into first and second groups of generators. The coherency analysis may comprise forming a first group of generators by selecting a reference generator from the plurality of generators, determining a first change in generator voltage angle for a given generator and a second change in generator voltage angle for the reference generator, and assigning the given generator to the first group of generators if the first change is within a certain amount of the second change. In some embodiments, a Single Machine Infinite Bus (SMIB) model is used to determine properties of a single power generator that is equivalent to a plurality of generators. SMIB equivalent parameters may be determined for the different groups.

In an example embodiment the different groups are identified by grouping together those generators having phase angles that remain the same within a given tolerance. For example, generators satisfying the following equation may be grouped together:

Δθᵢ−Δθᵣ<ε (9)

where θi is the power angle of a generator being considered for inclusion in a group, θr is the power angle of a reference generator, ε is a threshold (e.g. 10 degrees) and A indicates a change since a previous measurement (e.g. a difference in the power angle before and after a disturbance).

SMIB equivalent parameters may be determined in real time. In an example embodiment, real time SMIB equivalent, electrical power output and speed are continuously measured at all generator locations. As soon as the two coherent groups of generators (i.e., Group A and Group B) are identified using real time coherency (e.g. using Equation (9), the measured quantities and the inertia constants of the generators may be used to find SMIB equivalent parameters such as Pe and ω using Equations (5) and (6). The SMIB equivalent electrical power and speed deviation thus calculated may be applied as described herein to assess stability within the power system.

A simulation applied a sustained three phase fault at location 50D on bus 4 of the IEEE 12-bus grid. The duration of the fault was varied to obtain stable and unstable cases. As the fault was located close to generator G2, generator G2 was represented as a critical generator and the rest of the system was represented by an equivalent machine. An out-of-step relay was located at location 50E on the transmission line connecting bus 7 to bus 8. This transmission line is a weak line in the system and prone to losing synchronism.

The SMIB equivalent parameters Pe and ω were calculated using equations (5) and (6) respectively after gathering information from all of the generator locations. In an example application, the calculations are performed by a processor associated with the out-of-step relay.

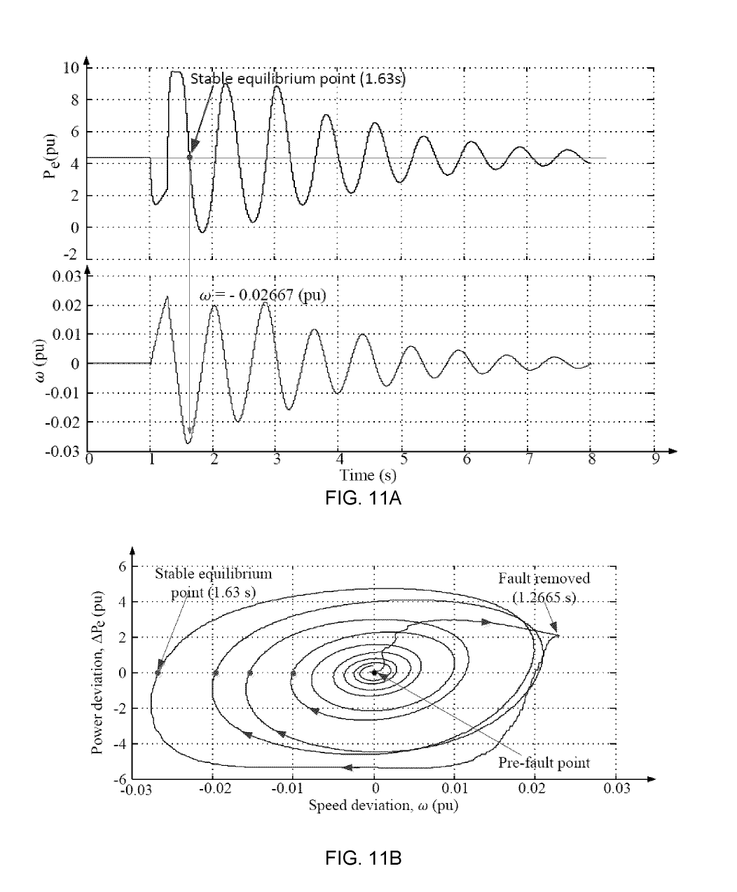

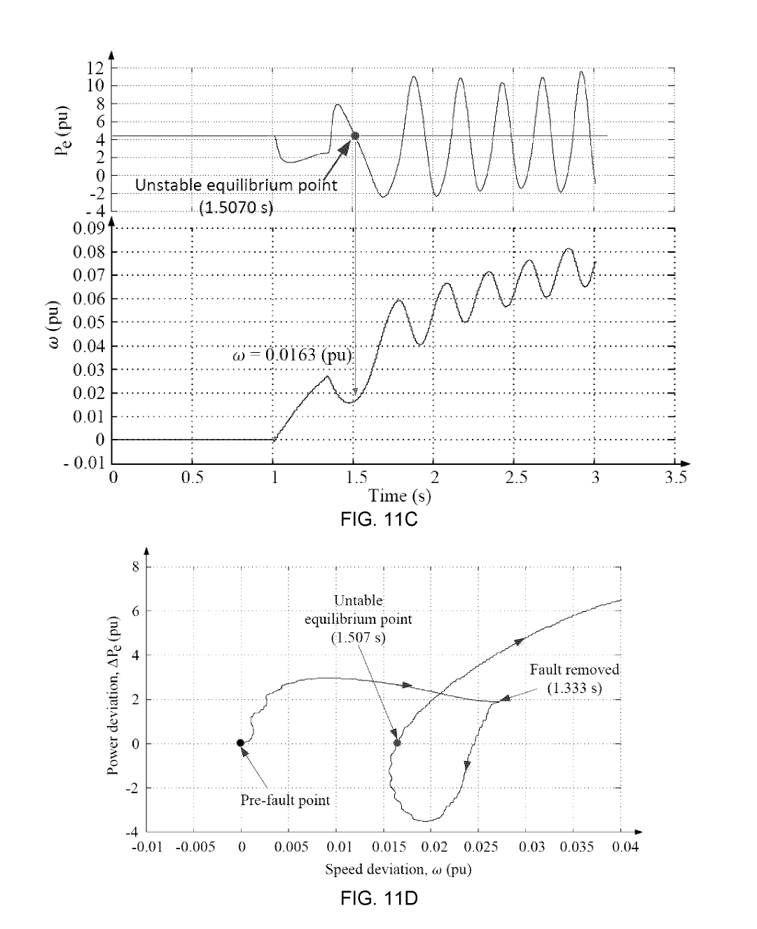

FIG. 11A shows the SMIB equivalent electrical power and speed for the fault at location 50D with a fault duration of 16 cycles (0.2665 s). The three phase fault was applied after 1 s. The generator G3, being a critical generator, oscillated against the rest of the system and hence the SMIB equivalent was calculated using Equations (1) and (2) following the onset of the disruption. The relay determined the first equilibrium point 0.63 s after fault inception. The speed deviation at the equilibrium point was found to be ω=−0.02667 (pu) and thus the relay identified a stable swing. FIG. 11B is a plot of power deviation versus speed deviation for the resulting stable power swing.

The fault duration was increased to 20 cycles (0.3332 s) and the system became unstable as shown in FIG. 11C. The speed determined at the equilibrium point is ω=0.0163 (pu) and the detection time was 0.507 s. FIG. 11D is a plot of power deviation versus speed deviation for the unstable power swing. The results of the simulation for different fault durations are summarized in Table III.

TABLE III
Summary of Simulation Results for Power
Swings using SMIB equivalent parameters

| Fault Duration, | | | |
|---|---|---|---|
| cycles | Fault Duration, s | Detection Time, s | Decision |
| 14 | 0.2333 | 0.5800 | stable |
| 16 | 0.2666 | 0.6300 | stable |
| 18 | 0.2998 | 0.7300 | stable |
| 20 | 0.3332 | 0.5070 | unstable |
| 22 | 0.3665 | 0.4565 | unstable |

Methods as described herein have been validated by running them in real time in a closed-loop simulation of a power system. Real time simulation employing hardware-in-the-loop testing is an accepted way to verify the performance of relays for use in power systems. Such testing is described, for example, in P. Forsyth, T. Maguire, and R. Kuffel, “Real time digital simulation for control and protection system testing,” in Proc. IEEE 35th Annual Power Electronics Specialists Conf. PESC 04, Aachen, Germany, vol. 1, June 2004, pp. 329-335.

A Digital Signal Processing (DSP) board was configured to implement a transient stability prediction system. The DSP board was programmed to apply a method like method 30 described herein. In one embodiment the DSP card was an ADSP-BF533™ EZ-kit lite board. The DSP board included one ADSP (model BF533™ Blackfin™) having a clock speed of 600 MHz; 2 MB FLASH memory; 32 MB SDRAM memory and an AD 1836 96 kHz audio codec. It was found that the DSP board could process an iteration of method 30 in one scan cycle (with scan cycles repeated at 48 kHz).

The transient stability prediction system was tested using signals from a real time digital simulator (RTDS™). The RTDS modelled a power system in detail with a time step of 50 microseconds. In the verification described herein, the power system was modelled using a development tool called RSCAD™. The power system model developed in RSCAD™ was compiled and simulated in the RTDS™. An IEEE 39-bus test system was modelled for performance verification of the transient stability prediction system. Real time signals from the RTDS™ were fed to the DSP board of the transient stability prediction system. Decisions (e.g. trip or no-trip signals generated at the DSP board) were fed back to RTDS™, forming a closed-loop testing system. It was found that the transient stability prediction system functioned well and was able to distinguish between stable and unstable power swings (including multi-swing instabilities).

Some embodiments of the invention provide methods for stability determination that are computationally simple, thereby facilitating implementations that use simple processors and/or can be executed with reduced computation.

Certain implementations of the invention comprise data processors (e.g. embedded processors, DSPs, microprocessors, workstations, and the like) which execute software instructions which cause the processors to perform a method of the invention. For example, one or more processors in a power system protection system or a numerical relay or a standalone transient stability detection system or a generator control system may implement methods as described herein by executing software instructions in a program memory accessible to the processors. The instructions comprise firmware in some embodiments. The data processor comprises an embedded processor in some embodiments. The invention may also be provided in the form of a program product. The program product may comprise any non-transitory medium which carries a set of computer-readable signals comprising instructions which, when executed by a data processor, cause the data processor to execute a method of the invention. Program products according to the invention may be in any of a wide variety of forms. The program product may comprise, for example, physical media such as magnetic data storage media including floppy diskettes, hard disk drives, optical data storage media including CD ROMs, DVDs, electronic data storage media including ROMs, flash RAM, or the like. The computer-readable signals on the program product may optionally be compressed or encrypted.

Some embodiments provide one or more databases and are configured to store in the one or more databases data for various power system disturbances. the stored data may include, for example, the results of methods described herein and how the power system behaved after the disturbances.

Where a component (e.g. a software module, processor, assembly, device, circuit, etc.) is referred to above, unless otherwise indicated, reference to that component (including a reference to a “means”) should be interpreted as including as equivalents of that component any component which performs the function of the described component (i.e., that is functionally equivalent), including components which are not structurally equivalent to the disclosed structure which performs the function in the illustrated exemplary embodiments of the invention.

While a number of exemplary aspects and embodiments have been discussed above, those of skill in the art will recognize certain modifications, permutations, additions and sub-combinations thereof. It is therefore intended that the following appended claims and claims hereafter introduced are interpreted to include all such modifications, permutations, additions and sub-combinations as are within their true spirit and scope.

### INTERPRETATION OF TERMS

Unless the context clearly requires otherwise, throughout the description and the
“comprise,” “comprising,” and the like are to be construed in an inclusive sense, as opposed to an exclusive or exhaustive sense; that is to say, in the sense of “including, but not limited to”.
“connected,” “coupled,” or any variant thereof, means any connection or coupling, either direct or indirect, between two or more elements; the coupling or connection between the elements can be physical, logical, or a combination thereof.
“herein,” “above,” “below,” and words of similar import, when used to describe this specification shall refer to this specification as a whole and not to any particular portions of this specification.
“or,” in reference to a list of two or more items, covers all of the following interpretations of the word: any of the items in the list, all of the items in the list, and any combination of the items in the list.
the singular forms “a,” “an,” and “the” also include the meaning of any appropriate plural forms.
Words that indicate directions such as “vertical,” “transverse,” “horizontal,” “upward,” “downward,” “forward,” “backward,” “inward,” “outward,” “vertical,” “transverse,” “left,” “right,” “front,” “back”, “top,” “bottom,” “below,” “above,” “under,” and the like, used in this description and any accompanying claims (where present) depend on the specific orientation of the apparatus described and illustrated. The subject matter described herein may assume various alternative orientations. Accordingly, these directional terms are not strictly defined and should not be interpreted narrowly.

It should be noted that terms of degree such as “substantially”, “about” and “approximately” as used herein mean a reasonable amount of deviation of the modified term such that the end result is not significantly changed. These terms of degree should be construed as including a deviation of up to ±10% of the modified term if this deviation would not negate the meaning of the term it modifies.

Specific examples of systems, methods and apparatus have been described herein for purposes of illustration. These are only examples. The technology provided herein can be applied to systems other than the example systems described above. Many alterations, modifications, additions, omissions and permutations are possible within the practice of this invention. This invention includes variations on described embodiments that would be apparent to the skilled addressee, including variations obtained by: replacing features, elements and/or acts with equivalent features, elements and/or acts; mixing and matching of features, elements and/or acts from different embodiments; combining features, elements and/or acts from embodiments as described herein with features, elements and/or acts of other technology; and/or omitting features, elements and/or acts from described embodiments.

It is therefore intended that the following appended claims and claims hereafter introduced are interpreted to include all such modifications, permutations, additions, omissions and sub-combinations as may reasonably be inferred. The scope of the claims should not be limited by the preferred embodiments set forth in the examples, but should be given the broadest interpretation consistent with the description as a whole.

1. A method for assessing transient stability and/or an out-of step condition of a power system, the method comprising:
obtaining a measure, Pm, of mechanical power driving a synchronous machine;
obtaining a measure, Pe, of electrical power output of the machine;
determining a sign of a measure, ω, of a rate that a phase angle of the synchronous machine is changing relative to a reference phase angle; and
if the difference, (Pm−Pe), of Pm and Pe changes sign from negative to positive, generating an output signal based on the sign of ω.

2. A method according to claim 1 wherein obtaining Pe comprises monitoring voltage and current at an output of the synchronous machine.

3. A method according to claim 2 wherein determining Pe comprises computing
\sqrt{3}IV cos φ
wherein: I is the magnitude of positive sequence current phasors; V is the magnitude of positive sequence voltage phasors; and, ω is an angle between the current phasors and voltage phasors.

4. A method according to claim 1 wherein obtaining Pm comprises measuring a torque driving the synchronous machine.

5. A method according to claim 1 wherein obtaining Pm comprises obtaining a pre-disturbance value for Pe.

6. A method according to claim 2 wherein monitoring the voltage and current is performed locally to a processor in which the method is being performed.

7. A method according to claim 2 comprising encoding measures of the voltage and current, transmitting the encoded measures to a processor at a location remote from the output of the synchronous machine and processing the encoded measures to provide the output signal at the remote location.

8. A method according to claim 1 comprising obtaining ω by processing electrical signals at an output of the synchronous machine.

9. A method according to claim 1 comprising applying the output signal in control of a protective device.

10. A method according to claim 9 wherein the protective device comprises a breaker and the method comprises operating the breaker to break a circuit in response to the sign of ω being positive.

11. A method according to claim 9 wherein the protective device comprises a breaker and the method comprises placing the breaker in a ready mode in response to the sign of ω being positive.

12. A method according to claim 9 wherein the protective device comprises a breaker and the method comprises operating the breaker to break a circuit in response to ω exceeding a threshold.

13. A method according to claim 12 wherein the threshold is a positive threshold.

14. A method according to claim 1 wherein the synchronous machine comprises a computed equivalent to a plurality of physical machines.

15. A method according to claim 14 comprising automatically grouping a plurality of generators into first and second groups and computing Pe and ω for the synchronous machine based on operating parameters of the generators of the first group.

16. A method according to claim 15 wherein automatically grouping the plurality of generators comprises applying a coherency analysis.

17. A method according to claim 14 or 15 wherein computing Pe and ω for the synchronous machine comprises computing a single machine infinite bus (SMIB) equivalent machine for the first group.

18. A method according to claim 14 wherein the computed equivalent comprises a single machine infinite bus (SMIB) equivalent machine.

19. A method according to claim 1 comprising determining the sign of ω each time the mechanical power and the electrical power are at an equilibrium point.

20. A method according to claim 1 wherein determining ω comprises comparing a current frequency of the synchronous machine to a nominal frequency.

21. A method according to claim 1 wherein determining ω comprises comparing a current frequency of the synchronous machine to a previous frequency of the synchronous machine.

22. A method according to claim 20 comprising determining the current frequency by performing a discrete Fourier transform (DFT) operation on a voltage signal of the synchronous machine.

23. Apparatus for monitoring transient stability and/or predicting an out-of-step condition in the presence of disturbances, such as a faults in a power system, the power system comprising a power generator the apparatus comprising:
an input for receiving information on voltage and current for the power generator;
a processing unit coupled to the input for receiving the information and processing the information to:
obtain a measure, Pm, of mechanical power driving a synchronous machine;
obtain a measure, Pe, of electrical power output of the machine;
determine a sign of a measure, ω, of a rate that a phase angle of the synchronous machine is changing relative to a reference phase angle; and
if the difference, (Pm−Pe), of Pm and Pe changes sign from negative to positive generate an output signal based on the sign of ω.

24. Apparatus according to claim 23 wherein the apparatus comprises a relay or breaker and the apparatus is configured to operate the relay or breaker to break a circuit in response to the sign of ω being positive.

25. Apparatus according to claim 23 wherein the apparatus comprises a relay or breaker and the apparatus is configured to place the relay or breaker into a ready mode in response to the sign of ω being positive.

26. Apparatus according to claim 23 wherein the processing unit is integrated with a control system of the relay or breaker.

27. Apparatus according to claim 24 wherein the processing unit is operable to generate the output signal prior to a voltage angle at the relay or breaker reaching 90 degrees.

28. Apparatus according to claim 23 comprising a torque meter connected to measure torque at a mechanical power input of the synchronous machine wherein the processing unit is configured to determine Pm based in part on a torque signal output by the torque meter.

29. Apparatus according to claim 23 wherein the processing unit is configured to predict a future trajectory of Pe and ω and to trigger an alarm if the future trajectory of Pe and ω has an equilibrium point at which Pm−Pe changes sign from negative to positive and ω is larger than a threshold value.

30. Apparatus according to claim 23 wherein the processing unit operates in real time to generate the output signal.

31. A method for assessing transient stability and/or an out-of step condition of a power system, the method comprising:
obtaining a measure, Pm, of mechanical power driving a synchronous machine;
obtaining a measure, Pe, of electrical power output of the machine;
obtaining a measure, ω, of a rate that a phase angle of the synchronous machine is changing relative to a reference phase angle;
predicting a future trajectory of Pe and ω;
triggering an alarm if the future trajectory of Pe and ω has an equilibrium point at which the difference Pm−Pe changes sign from negative to positive and ω is larger than a threshold value.

32. Apparatus for monitoring transient stability and/or predicting an out-of-step condition in the presence of disturbances, such as a faults in a power system, the power system comprising a power generator the apparatus comprising:
an input for receiving information on voltage and current for the power generator;
a processing unit coupled to the input for receiving the information and processing the information to:
obtain a measure, Pm, of mechanical power driving a synchronous machine;
obtain a measure, Pe, of electrical power output of the machine;
obtain a measure, ω, of a rate that a phase angle of the synchronous machine is changing relative to a reference phase angle;
predict a future trajectory of Pe and ω;
trigger an alarm if the future trajectory of Pe and ω has an equilibrium point at which the difference Pm−Pe changes sign from negative to positive and ω is larger than a threshold value.

33.-34. (canceled)
